(19) United States
(12) Patent Application Publication
(10) Pub. No.: US 2026/0177607 A1
(43) Pub. Date: Jun. 25, 2026

(54) SYSTEMS AND METHODS FOR HIGHLY-PARALLEL TESTING WITH THERMAL CONTROL

(71) Applicant: AEM Singapore Pte. Ltd., Singapore (SG)

(72) Inventors: Kenneth B. UEKERT, Grand Junction, CO (US); Samer KABBANI, Laguna Niguel, CA (US); Terry Sinclair CONNACHER, Tempe, AZ (US); Sasa NESTOROVIC, Escondido, CA (US); Kijoo SUNG, Yongin-si (KR); Nikolay O. VOZDOLSKY, San Diego, CA (US); Enrique ALEMAN, Temecula, CA (US)

(21) Appl. No.: 19/431,636

(22) Filed: Dec. 23, 2025

Related U.S. Application Data
(60) Provisional application No. 63/738,701, filed on Dec. 24, 2024.

(51) Int. Cl. G01R 31/28

(52) U.S. Cl. CPC G01R 31/2877; G01R 31/2863; G01R 31/2867; G01R 31/2875

(57) ABSTRACT

Disclosed herein is a test handler and corresponding test system for thermally controlling a plurality of devices under test (DUTs) by use of one or more thermal heads, while they are being tested in parallel. In some embodiments, a thermal head comprises a heat exchanger assembly, a piston block assembly, and a match plate assembly. In some embodiments, each individual DUT may have its temperature controlled independently by components, such as individual heaters, within the thermal head. The test handler may comprise a T-tray loading area, a temperature pre-soak area, a testing area, a temperature de-soak area, and a JEDEC tray loading area. In some embodiments the pick and place mechanism in the T-tray loading area may change the pitch or grid location of DUTs picked from a transport medium on the fly to a different pitch or location grid to match the socket placement on the tester load board.

### CROSS-REFERENCE TO RELATED APPLICATION

This application claims priority to and the benefit of U.S. Provisional Patent Application No. 63/738,701, filed Dec. 24, 2024, the entire contents of which are incorporated herein by reference for all purposes.

### FIELD

The present disclosure relates to systems and methods for controlling one or more temperatures of integrated circuit (IC) packages, and more specifically, handling and controlling multiple packages during testing.

### BACKGROUND

Integrated circuit (IC) chips are typically encased in a chip “package” that often includes a lead frame or substrate, interconnects from the chip to the lead frame or substrate, and a casing material such as a mold compound. Terminals on the package (e.g., leads or solder balls) allow for electrical connection to the package and through the package to the chip(s) inside. To accomplish electrical testing of a package and its chip(s), the package may be picked up and placed into an electrical test socket. In some cases, a plurality of packages may be handled at the same time (e.g., a plurality of packages may be picked up simultaneously and placed into a plurality of corresponding test sockets at the same time). In some cases, the plurality of packages may be thermally controlled while being tested. For example, there may be a set point temperature and thermal control means to maintain the packages at or near the set point temperature during a desired time interval. A package undergoing testing as described here may be referred to as a “Device Under Test” or a “DUT.”

Traditional test handling systems utilize a chambered approach to create a temperature-controlled environment to allow the ICs to reach the desired test temperature. While a chambered approach may be an effective way to control the temperature of many devices being tested in parallel, thermal chambers have many shortcomings, including, but not limited to, site-to-site temperature variations, significant thermal stress on mechanisms housed inside the chamber, and no ability to actively dissipate heat generated from the ICs during testing. The present disclosure solves these problems in the prior art.

### SUMMARY

Disclosed herein are a test handler and a corresponding test system for thermally controlling a plurality of devices under test (DUTs) by use of one or more thermal heads while they are being tested in parallel. In some embodiments, a thermal head comprises a heat exchanger assembly, a piston block assembly, and a match plate assembly. Each individual DUT may have its temperature controlled independently by components, such as individual heaters, within the thermal head. The test handler may comprise a T-tray loading area, a temperature pre-soak area, a testing area, a temperature de-soak area, and a JEDEC tray loading area. In some embodiments, the pick and place mechanism in the T-tray loading area may change the pitch or grid location of DUTs picked from a transport medium (such as a JEDEC tray) on the fly to a different pitch or location grid to match the socket placement on the tester load board.

In addition to DUT-level thermal management provided through the thermal heads, some embodiments can further address temperature control at the load board and socket level. For example, the load board may incorporate convective flow channels configured to direct temperature conditioned air to selected regions of the board, and/or conductive structures such as thermally conductive frames with internal fluid channels that can supply heating or cooling directly to the PCB and its components. These convective and/or conductive mechanisms can function as a load board conditioning, providing active temperature regulation of the load board, sockets, and/or adjacent components. Such thermal-conditioning mechanisms can reduce load-board temperature gradients, improve socket-to-socket thermal uniformity, and/or enhance the accuracy and stability of DUT testing.

Some embodiments may incorporate a variety of temperature conditioning and force-management mechanisms to enhance accuracy and throughput during parallel testing. For example, localized heater elements such as flex film heaters or rigid heaters may provide integrated heating and temperature sensing to enable precise, independent thermal control at each DUT location. A thermal controller may employ demultiplexed heater-driving and temperature-sensing channels to efficiently manage large numbers of thermal zones. The piston block assembly may include adjustable-force pistons, pivots, and/or thermal interfaces to maintain uniform force and optimal thermal contact across DUTs. Additionally, conductive soak plates may pre-condition DUT temperatures before and after testing, and grouped thermal-control architectures may provide combined heating or cooling for subsets of DUTs. The handler may also operate in high-capacity modes, such as by utilizing vertically oriented T-trays that carry up to 256 DUTs each for parallel testing.

In some embodiments, the system may incorporate an Active Force Control (AFC) mechanism within a pick and place subsystem. An AFC mechanism can enable a user or controller to specify a desired DUT-contact force (e.g., via a user interface) and regulate actuator torque to achieve that force consistently across devices, reducing variations due to DUT geometry, vacuum pick characteristics, and/or mechanical tolerances. AFC thereby improves handling reliability and prevents excessive loading on sensitive DUT surfaces during high-throughput operations.

A system for thermally controlling a plurality DUTs is disclosed. The thermal control system comprises: one or more thermal heads configured to simultaneously control a temperature of a plurality of devices under test (DUTs), at least one of the thermal heads comprising: one or more heat exchanger assemblies (HEAs) configured to heat or cool one or more piston block assemblies (PBAs); wherein the one or more PBAs are configured to apply force to one or more plate assemblies and transfer heat or cooling to the one or more plate assemblies; and wherein the one or more plate assemblies are configured to heat or cool the plurality of DUTs.

Additionally or alternatively, in some embodiments, the plurality of DUTs comprises more than 32 DUTs.

Additionally or alternatively, in some embodiments, at least one of the one or more HEAs comprise one or more of: a liquid-cooled cold plate, a cooling medium, a Peltier device, or a heat exchanger configured to adjust one or more temperatures of the one or more HEAs.

Additionally or alternatively, in some embodiments, at least one of the PBAs comprises one or more piston blocks, at least one of the one or more piston blocks comprising one or more pistons.

Additionally or alternatively, in some embodiments, at least one of the PBAs comprises one or more seal rings.

Additionally or alternatively, in some embodiments, at least one of the one or more piston blocks further comprises one or more pivots comprising a curved surface configured to fit against a curved surface of the one or more pistons, wherein the one or more pivots are configured to rotate to apply constant force to a receiving surface of at least one of the one or more plate assemblies.

Additionally or alternatively, in some embodiments, the one or more piston blocks further comprise one or more thermal interfaces configured to transfer heat between the one or more pistons and the one or more pivots.

Additionally or alternatively, in some embodiments, at least one of the one of more plate assemblies comprises: one or more pusher blocks, at least one of the one or more pusher blocks comprises one or more mandrels; one or more pedestals attached to the one or more pusher blocks; and one or more flex film heaters, wherein the one or more flex film heaters are flexible and configured to transfer heat to at least one of the one or more pusher blocks.

Additionally or alternatively, in some embodiments, at least one of the one or more plate assemblies comprises the one or more flex film heaters coupled to at least one of the one or more pusher blocks, wherein the one or more flex film heaters are configured to individually adjust a temperature of at least one of the pedestals.

Additionally or alternatively, in some embodiments, a portion of at least one of the one or more flex film heaters is wrapped around at least one of the one or more mandrels, and the at least one mandrel is configured to push the portion of the at least one flex film heater into contact with the at least one pusher block.

Additionally or alternatively, in some embodiments, at least one of the one or more flex film heaters comprises traces configured to provide heat, sense temperature, or both.

Additionally or alternatively, in some embodiments, at least one of the one or more flex film heaters comprises a connector at a distal tip configured to connect to power delivery circuitry configured to deliver power to the one or more flex film heaters.

Additionally or alternatively, in some embodiments, the thermal control system further comprises a demultiplexer configured to control a temperature of a plurality of zones of the one or more thermal heads.

Additionally or alternatively, in some embodiments, at least one of the one or more plate assemblies comprises: one or more pusher blocks; one or more pedestals attached to the one or more pusher blocks; one or more rigid heaters positioned between the one or more pusher blocks and the one or more pedestals, wherein the one or more rigid heaters are configured to heat the one or more pedestals; and one or more flex cables or wires electrically coupled to the one or more rigid heaters, wherein the one or more flex cables or wires are configured to supply voltages or currents to the one or more rigid heaters.

Additionally or alternatively, in some embodiments, the at least one plate assembly comprises the one or more rigid heaters coupled to each of the one or more pusher blocks, wherein the one or more rigid heaters are configured to individually adjust a temperature of the one or more pedestals.

Additionally or alternatively, in some embodiments, the thermal control system further comprises one or more convective flow channels configured to carry temperature conditioned air.

Additionally or alternatively, in some embodiments, the thermal control system further comprises one or more conductive temperature conditioning structures comprising one or more internal fluid channels configured to transfer heat to or from one or more structures configured to support or electrically couple the DUTs.

Additionally or alternatively, in some embodiments, the thermal control system further comprises one or more thermal controllers configured to control a temperature of the one or more thermal heads.

Additionally or alternatively, in some embodiments, the one or more thermal controllers comprise one or more FPGAs and a plurality of demultiplexed channels configured to control the temperature of the plurality of DUTs.

A method for temperature-controlled device testing is disclosed. The method comprises: inserting a plurality of devices under test (DUTs) into a plurality of sockets of a testing tray; positioning one or more pedestals of one or more thermal heads against the plurality of DUTs; changing a temperature of the plurality of DUTs to a first temperature by changing a temperature of the one or more pedestals to the first temperature; testing the DUTs at the first temperature; changing the temperature of the plurality of DUTs to a second temperature by changing a temperature of the one or more pedestals to the second temperature, wherein the second temperature is different than the first temperature; and testing the DUTs at the second temperature. Additionally or alternatively, the method further comprises controlling a force with which the plurality of DUTs are inserted into the plurality of sockets.

A test handler system for adjusting a configuration of DUTs without releasing the DUTs from a pick and place head is disclosed. The system comprises a pick and place head comprising a plurality of pick tips configured to pick up a plurality of devices under test (DUTs), wherein at least one of the pick tips comprises a plurality of positioning mechanisms, comprising a first positioning mechanism for adjusting a position of the pick tip in a first direction and a second positioning mechanism for adjusting a position of the pick tip in a second direction, wherein a configuration of the plurality of DUTs is adjusted without releasing the plurality of DUTs from the plurality of pick tips. Additionally or alternatively, the pick and place head can be configured to regulate a force applied by the pick tips to the DUTs based on a user-selected force setpoint.

A thermal conditioning subsystem is disclosed. The system comprises a primary refrigerant circuit configured to receive a primary refrigerant, a first fluid circuit configured to circulate a first fluid, a second fluid circuit configured to circulate a second fluid, a first heat exchange interface configured to transfer heat between the primary refrigerant and the first fluid, and a second heat exchange interface configured to transfer heat between the primary refrigerant and the second fluid. The subsystem is configured to supply the first fluid and the second fluid to one or more temperature controlled elements of a test system.

It will be appreciated that any of the variations, aspects, features, and options described in view of the systems and methods apply equally to the methods and vice versa. It will also be clear that any one or more of the above variations, aspects, features, and options can be combined. It should be understood that the invention is not limited to the purposes mentioned above, but may also include other purposes, including those that can be recognized by one of ordinary skill in the art.

### BRIEF DESCRIPTION OF THE FIGURES

FIG. 1 illustrates a conceptual schematic of an exemplary test handler, according to some embodiments.

FIG. 2A illustrates an exemplary pick and place head, according to some embodiments.

FIG. 2B illustrates an exemplary two-stage AFC picking sequence, according to some embodiments.

FIG. 2C illustrates an exemplary torque to force relationship that may be used for AFC, according to some embodiments.

FIG. 3 illustrates an exploded view of an exemplary T-tray, according to some embodiments.

FIGS. 4A and 4B illustrate exemplary carriers and structures thereof for controlling the position of DUTs, according to some embodiments.

FIG. 5 illustrates an exemplary conductive soak plate assembly, according to some embodiments.

FIG. 6A illustrates a conceptual schematic of an exemplary thermal head, according to some embodiments.

FIG. 6B illustrates an exemplary thermal head, according to some embodiments.

FIGS. 7A-7C illustrate an exemplary piston block assembly, according to some embodiments.

FIG. 8A illustrates an exemplary match plate assembly, according to some embodiments.

FIG. 8B illustrates a sectional view of an exemplary match plate assembly, according to some embodiments.

FIG. 8C illustrates a portion of an exemplary match plate assembly with a heating portion and flex film heater, according to some embodiments.

FIGS. 9A and 9B illustrate an exemplary match plate assembly, according to some embodiments.

FIG. 10 illustrates an exemplary grouped thermal control, according to some embodiments.

FIG. 11 illustrates a top view of an exemplary T-tray loaded with DUTs and a load board with sockets, according to some embodiments.

FIG. 12A illustrates a conceptual schematic of an exemplary DUT coupling with a socket on a load board, according to some embodiments.

FIG. 12B illustrates a conceptual schematic of an exemplary load board, DUT, pedestal, and convective flow channels, according to some embodiments.

FIG. 12C illustrates a conceptual schematic of an exemplary load board, DUT, pedestal, and a fluid-based conductive temperature-control mechanism, according to some embodiments.

FIG. 12D illustrates an exemplary arrangement of distributed load board conditioning structures and an internal fluid-delivery system, according to some embodiments.

FIG. 12E illustrates a sectional view of an exemplary internal fluid-delivery pathway supplying load board conditioning structures, according to some embodiments.

FIG. 13 illustrates an exemplary configuration of a thermal control system, according to some embodiments.

FIG. 14 illustrates an exemplary graphical user interface for simulation and analytics, according to some embodiments.

FIG. 15A illustrates an exemplary internal chiller subsystem, according to some embodiments.

FIG. 15B illustrates an exemplary manifold of an internal chiller subsystem, according to some embodiments.

FIG. 15C illustrates an exemplary chiller base assembly of an internal chiller subsystem, according to some embodiments.

FIG. 16A illustrates a first portion of an internal chiller subsystem, according to some embodiments.

FIG. 16B illustrates a second portion of the internal chiller subsystem, according to some embodiments.

FIG. 16C illustrates a control portion of the internal chiller subsystem, according to some embodiments.

FIG. 17A illustrates an exemplary process for priming an internal chiller subsystem, according to some embodiments.

FIG. 17B illustrates an exemplary process for ramping a cold cycle of an internal chiller subsystem, according to some embodiments.

FIG. 17C illustrates an exemplary process for running a cold cycle of an internal chiller subsystem, according to some embodiments.

It will be appreciated that any of the variations, aspects, features, and options described in view of the systems apply equally to the methods and vice versa. It will also be clear that any one or more of the above variations, aspects, features, and options can be combined.

### DETAILED DESCRIPTION

Disclosed herein is a test handler and a corresponding test system for thermally controlling a plurality of devices under test (DUTs) by use of one or more thermal heads while the DUTs are being tested. The DUTs may be tested in parallel. A thermal head may comprise a heat exchanger assembly, a piston block assembly, and a match plate assembly. Each individual DUT may have its temperature controlled independently by components within the thermal head, such as individual heaters. The test handler may comprise a T-tray loading area, a temperature pre-soak area, a testing area, a temperature de-soak area, and a JEDEC tray loading area. In some aspects, the pick and place mechanism in the T-tray loading area may change the pitch or grid location of DUTs picked from a transport medium (e.g., a JEDEC tray) on the fly to a different pitch or location grid to match the socket placement on the tester load board.

Modern memory devices, particularly stacked-die DRAM and NAND packages, present several rapidly emerging challenges for high-parallel test environments. Increasing device power densities and the presence of vertically stacked dies create significant temperature gradients across the DUT, while near-DUT test electronics on the load board generate substantial localized heating that can distort test temperature set points. At the same time, memory manufacturers require tighter temperature accuracy across very large test arrays (e.g., hundreds of simultaneous DUTs), extended temperature ranges, and improved reliability for applications such as automotive memory. Variable DUT package heights further introduce risk of device damage unless force during pick-and-place operations is actively controlled. Conventional chamber-based systems struggle with these combined requirements due to slow thermal response, large site-to-site variation, and mechanical degradation of chamber-housed components. Accordingly, there is a need for a chamberless, conductive thermal-control architecture that provides enhanced load-board conditioning, high-accuracy temperature control at both the group and individual DUT levels, and low-force, repeatable handling of sensitive memory packages in high-throughput test environments.

The systems and methods described herein address these challenges by providing a chamberless, thermal-control architecture that yields substantially improved thermal accuracy, reliability, and/or test efficiency. In some embodiments, the systems disclosed within can support load board conditioning (LBC) to address the significant heat generated by near-DUT tester electronics. The system may also accommodate new sub-5 nm DUTs exhibiting increased watt density and stacked-die packages that introduce vertical temperature gradients. In some examples, high site-to-site temperature accuracy may be achieved at large parallelism levels, such as accuracy on the order of approximately ±3° C. across 512 sites, or on the order of approximately ±1° C. across 512 sites. The thermal architecture may further support a wide operational temperature range, such as from approximately −55° C. to approximately 140° C.

Conventional thermal-control approaches used in some final test environments have relied on passive or convective mechanisms, often implemented within large thermal chambers. Such configurations may exhibit slow response times, large thermal masses, limited temperature precision across many devices, and mechanical stresses resulting from repeated temperature cycling. The present disclosure introduces a conductive thermal control architecture that may operate in different modes depending on application requirements, including embodiments that provide Active Group Control (AGC), in which a defined set of DUT sites share a thermally regulated zone, and Active Site Control (ASC), in which each DUT site is capable of being thermally regulated independently. These modes allow the system to support high-parallel, high-accuracy temperature control for modern memory devices without relying on chamber-based thermal structures.

In some embodiments, the disclosed systems may operate in an Active Group Control (AGC) mode. In AGC configurations, a defined subset of DUT sites is thermally regulated together within a shared thermal zone. This mode may provide improved temperature stability across multiple devices subjected to elevated power densities, conditions under which conventional chamber-based thermal systems may exhibit increased temperature variation. AGC operation allows the system to maintain controlled die temperatures across a group of DUTs while accommodating substantial heat generated during parallel testing.

In some embodiments, the system may operate in an Active Site Control (ASC) mode. In ASC configurations, each DUT location can be thermally regulated independently using a dedicated heating element or temperature-control device associated with that site. This per-site approach may provide improved temperature uniformity across a large number of DUTs, including conditions where individual devices exhibit differing or elevated power densities. By allowing each DUT to receive individually controlled thermal input, ASC operation may reduce temperature variation that could otherwise arise from differences in device construction or thermal loading across the test array.

The handler architecture may also improve system reliability. In some embodiments, the system may simplify material flow, and can support high unit-per-hour (UPH) operation, with example configurations achieving throughput values such as greater than 41,000 UPH at 512 sites. The system may utilize reduced part counts relative to traditional chamber-based handlers and may eliminate the need for thermal chambers altogether. Device handling reliability may be improved through mechanisms that reduce device damage or jam events, including embodiments configured to apply controlled forces to DUT surfaces during pick-and-place operations.

The overall cost of ownership may be reduced through several factors. In some embodiments, the thermal architecture may reduce or eliminate liquid-nitrogen consumption. Change-kit complexity and cost may also be reduced through modular components. Optional features, such as auto-teach or vision-based subsystems, may further streamline setup and alignment procedures. The chamberless thermal design may also reduce or eliminate defrost cycles and may support new material flow options, including hot and cold allocations, thereby improving factory utilization.

In some embodiments, the system may further incorporate optional software tools configured to assist with production optimization and throughput management. Such tools may, for example, simulate unit-per-hour (UPH) performance under various handler configurations, test conditions, or sorting strategies, and may include modes that allow accelerated evaluation of projected throughput outcomes. Additional implementations may provide automated analyses of production trends and/or bottlenecks and may generate optimization recommendations based on observed system behavior. In certain cases, a user interface or dashboard may be provided to visualize operational metrics, evaluate alternative handling or sorting approaches, and/or suggest pick-and-place configurations suited to particular test scenarios.

The following description is presented to enable a person of ordinary skill in the art to make and use various embodiments. Descriptions of specific devices, techniques, and applications are provided only as examples. These examples are being provided solely to add context and aid in the understanding of the described examples. It will thus be apparent to a person of ordinary skill in the art that the described examples may be practiced without some or all of the specific details. Other applications are possible, such that the following examples should not be taken as limiting. Various modifications in the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown but are to be accorded the scope consistent with the claims.

Various techniques and process flow steps will be described in detail with reference to examples as illustrated in the accompanying drawings. In the following description, numerous specific details are set forth in order to provide a thorough understanding of one or more aspects and/or features described or referenced herein. It will be apparent, however, to a person of ordinary skill in the art, that one or more aspects and/or features described or referenced herein may be practiced without some or all of these specific details. In other instances, well-known process steps and/or structures have not been described in detail in order to not obscure some of the aspects and/or features described or referenced herein.

In the following description of examples, reference is made to the accompanying drawings which form a part hereof, and in which it is shown by way of illustration specific examples that can be practiced. It is to be understood that other examples can be used, and structural changes can be made without departing from the scope of the disclosed examples.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. It will also be understood that the term “same,” when used in this specification, refers to the stated feature as being identical or within a certain range (e.g., 1%, 5%, etc.) from identical.

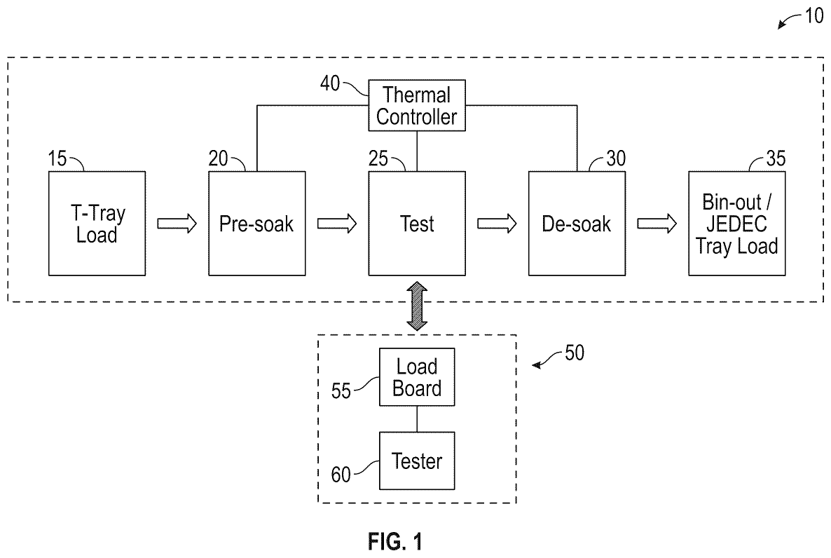

FIG. 1 illustrates a conceptual schematic of an exemplary test handler 10 according to some embodiments. Test handler 10 may be configured for testing of DUTs and may include the capability to control the temperature of the DUTs while they are being tested. The test handler 10 may comprise multiple physical areas that have different primary functions. As shown in FIG. 1, DUTs may travel from area to area in a sequential fashion, such as from left to right in the figure, although other arrangements of travel may be possible. The test handler 10 may comprise a T-tray load area 15, a pre-soak area 20, a test area 25, a de-soak area 30, a bin-out area 35, and a thermal controller 40.

The test handler 10 may comprise a T-tray load area 15. In T-tray load area 15, the test handler 10 may remove DUTs (e.g., memory packages with one or more chips inside them) from trays used for shipping and handling (e.g., JEDEC trays) and place them within trays used for transporting the DUTs through the test handler 10. These trays can be referred to as “test-trays” or “T-trays.”

The test handler 10 may comprise a pre-soak area 20 and a de-soak area 30. Pre-soak area 20 may be used to bring the DUTs to a temperature near the temperature desired for the test operation in test area 25. De-soak area 30 may be used to change the temperature of the DUTs from the test temperature in test area 25 to another desired temperature (e.g., room temperature).

In many traditional handlers, pre-soak or de-soak areas were comprised of chambers wherein a gas flow (e.g., air) was blown over the DUTs to change or maintain their temperature by convective heat transfer from the gas to the DUTs. The desired change in temperature may be an increase in temperature (e.g., heating) or a decrease in temperature (e.g., cooling). In some embodiments of the present disclosure, conductive heat transfer may be used to control the temperature of the DUTs while in the pre-soak area 20 or de-soak area 30. Conductive heat transfer may provide a more uniform temperature of the DUTs and faster heating or cooling of the DUTs.

The test handler 10 may comprise test area 25. Test area 25 may comprise test system 50, wherein test system 50 may be external to test handler 10 and may be coupled electrically and physically to test handler 10. Test system 50 may comprise load board 55 and tester 60.

The test handler 10 may comprise a bin-out area 35 where tested DUTs are segregated by their test results into different “bins,” and DUTs with the same bin category are transferred from the T-trays into JEDEC trays.

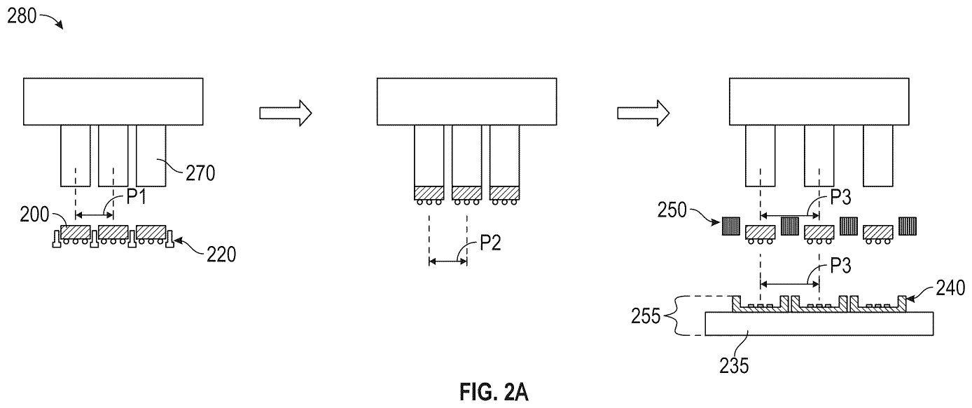

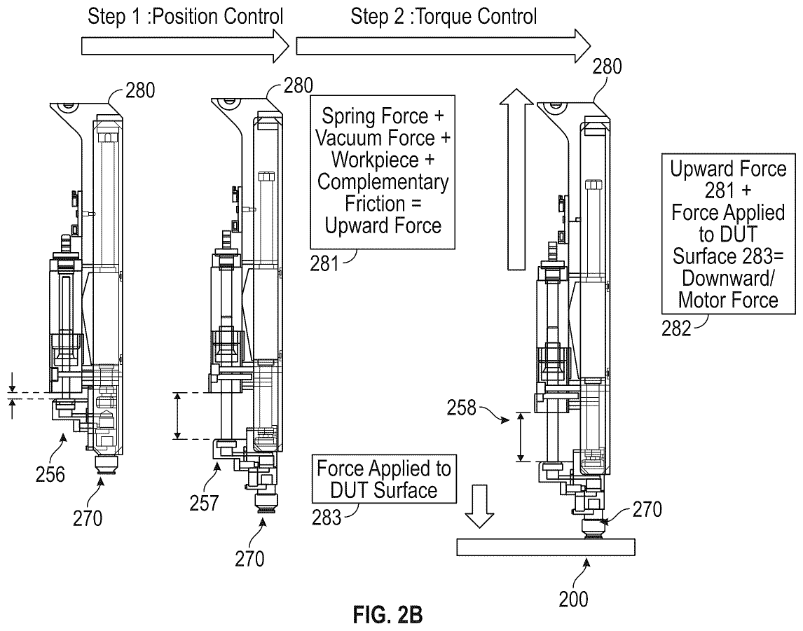

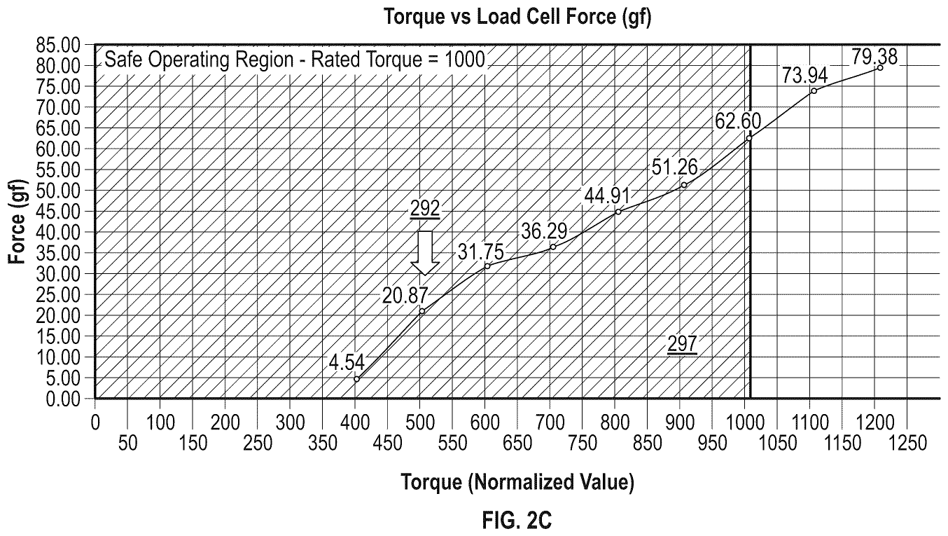

FIG. 2A illustrates the operation of pick and place head 280, according to some embodiments. Pick and place head 280 may comprise pick tips 270 within a T-tray load area (e.g., the T-tray load area 15 of FIG. 1). Initially, the pick tips 270 may be spaced with an appropriate pitch P1 (in an X-direction, Y-direction, or both X- and Y-directions) to match the pitch of the DUTs 200 held within a JEDEC tray 220. The pick tips 270 may pick up the DUTs 200 and adjust the pitch of the DUTs from pitch P1 to pitch P2 on the fly (e.g., in real time) and without releasing the DUTs 200, such that the pitch P2 is different from pitch P1. In some examples, the pitch may refer to the distance between the center of a first DUT and the center of a second DUT along, e.g., the X-axis. Pitch P2 may be a pitch that is configured for transportation of the DUTs 200 and/or a pitch that matches a pitch of sockets 240.

The pick and place head 280 may be configured such that it may adjust both the X-axis and Y-axis pitches simultaneously in one concurrent move. For example, pick tips 270 of pick and place head 280 may each comprise at least two positioning mechanisms. The at least two positioning mechanisms may comprise at least one X-axis positioning mechanism for adjusting the X-axis position of the pick tip 270, and at least one Y-axis positioning mechanism for adjusting the Y-axis position of the pick tip 270. In some embodiments, X-axis and Y-axis pitches may be adjusted one after the other while in the same move operation by activating the X-axis positioning mechanism and the Y-axis positioning mechanism in sequence, so that the resultant pitch change from P1 to P3 may be completed within the move. In some embodiments, both the X-axis and Y-axis pitches may be adjusted simultaneously by having the positioning mechanism for each axis be active at the same time. A positioning mechanism may be any mechanism as known in the art, and may comprise one or more pneumatic or hydraulic cylinders, one or more pneumatic or hydraulic diaphragms, one or more stepper motors, one or more linear motors, one or more servo motors, one or more electromagnetic actuators, one or more rotary motors, one or more electromechanical actuators, one or more piezoelectric actuators, and/or one or more voice coils. In some embodiments, pick tips 270 may each comprise a Z-axis positioning mechanism.

The pick tips 270 may adjust the pitch of DUTs 200 from P2 to P3. The pick and place head 280 may release the DUTs 200 into the T-tray 250. A pitch of the DUTs may refer to the distance from one DUT to another DUT. A pitch may be different in an x-direction than a y-direction, or it may be the same in both directions. Location of the DUTs may refer to a specific x- and y-location for each DUT. The pitch P3 and location of the DUTs 200 while in the T-tray 250 may match the pitch P3 and location of the sockets 240 that are mounted on a PCB 235 and that are parts of the load board 255. In FIG. 2A, load board 255 is shown for reference and may not be found within a T-tray load area (e.g., T-tray load area 15 of FIG. 1) but may be located in a test area (e.g., test area 25 of FIG. 1). To summarize, the pick and place head 280 has the ability, on the fly and without releasing the DUTs 200, to change the pitch (for example, in both the X-axis and Y-axis in a single simultaneous move) and location of DUTs 200 picked from a JEDEC tray 220 in order to match the pitch and location of the DUTs 200 to the sockets 240 on the load board 255.

The pick and place head 280 may comprise one or more force actuators such that the Z-direction pick force or place force of the pick tips 270 can be controlled. The force actuators may be linear motors or any other suitable force mechanism. The one or more force actuators may allow for independent Z-level control, such that the Z-pick height may be controlled individually for each pick tip 270. The force actuators may be coupled with linear encoders. In some embodiments, there may be a dedicated linear encoder for each pick tip 270, which may allow the linear encoder to sense and provide information on position, direction of travel, or speed of the pick tip 270.

Having force actuators and linear encoders for each pick tip 270 may have multiple advantages. For example, the pick tip 270 may be able to learn the Z-axis pick height for each pick tip 270 due to pick tip 270 force feedback coupled with position. In another example, the pick tip 270 may be able to exert independent and integrated force control per pick tip 270. In another example, using a closed-loop feedback of encoder count and force, the pick tip 270 may have the ability to detect instances and corresponding locations where there is no DUT 200, double-stacked DUTs 200, tilted DUTs 200, or other anomalies. In some embodiments, the force actuators and associated sensing elements interface with an Active Force Control (AFC) algorithm configured to regulate the normal force applied during DUT engagement. AFC may dynamically modulate actuator torque based on measured and/or estimated reaction forces to maintain a commanded force setpoint during the picking operation.

Additionally, the force actuators may have linear motors, which may be fast (e.g., speeds of at least 2 m/s, at least 5 m/s, or faster) and may have low mass (e.g., less than 0.5 kg for a travel length of 10 cm, or less than 0.3 kg for a travel length of 10 cm). Linear motor mass may be reduced by comprising a moving coil that does not include iron. The force actuators may be able to support much faster accelerations and velocities than a typical global Z-axis force actuator. This advantage in speed may allow for the same overall throughput of DUTs 200 picked and placed, but with the need for fewer pick and place gantries compared to a traditional system with global Z-axis force actuators. For example, a traditional pick and place system may utilize 5 gantries whereas the number of gantries in the instant invention may utilize only 3 gantries while obtaining the same throughput.

In some embodiments, the pick and place head 280 may incorporate an Active Force Control (AFC) mechanism configured to apply a user-selectable, regulated force to the surface of each DUT during pick, transport, and/or placement operations. AFC may enable a controller and/or operator to specify a desired target force (e.g., via a user interface), and the system can then modulate actuator output to maintain that target force independent of DUT height variation, vacuum characteristics, spring responses, and/or frictional effects within the pick-tip assembly. In some embodiments, the pick operation may be divided into a first stage in which the pick tips move to a commanded positional setpoint, followed by a second stage in which the actuator torque is dynamically adjusted so that the resulting normal force at the DUT interface matches the commanded force. AFC may therefore provide consistent and repeatable contact forces across large populations of DUTs, enhance protection of sensitive DUT surfaces, and combine the speed advantages of high-velocity position control with the precision of closed-loop force regulation.

FIG. 2B illustrates an exemplary two-stage AFC picking sequence, according to some embodiments. The process can begin with Step 1: Position Control, in which a pick tip 270 is moved from a defined home position 256 toward a T-tray pre-pick position 257 located above a DUT 200 held within a T-tray 250. During this positional approach, the actuator can operate in a position-regulated mode, allowing the pick tip 270 to rapidly reach a commanded location. Upon reaching the pre-pick position 257, the system can transition to Step 2: Torque Control, in which the system can regulate the normal force applied to the DUT. As shown, multiple upward forces (e.g., including spring force, vacuum force, workpiece reaction force, and complementary friction) may act upon the pick-tip assembly. These forces can combine to form a resultant upward force 281. The system computes and applies a corresponding downward actuator force 282, such that the net contact force at the DUT surface 283 can match a commanded user-selected value. The pick tip 270 can subsequently reach the pick position 258, where the controlled force is maintained as the DUT 200 is engaged. This two-stage sequence can enable fast positional movement followed by precise, closed-loop force regulation during DUT handling.

FIG. 2C illustrates an exemplary torque-to-force relationship that may be used for AFC, according to some embodiments. As shown, a calibration 292 curve may be generated that correlates a commanded actuator torque to a resulting load-cell force applied to a DUT surface. By referencing this curve, the system may determine the force that will be applied at the pick tip for any selected torque value. A target-torque region 297 may be established, such that choosing a torque within this region yields a corresponding, predictable contact force suitable for DUT handling. During operation, a controller may select a desired torque setpoint that aligns with the user-defined force requirement, ensuring that each DUT experiences a consistent and repeatable picking force despite variations in DUT height, surface conditions, or mechanical tolerances in the pick-tip assembly. This torque-to-force mapping can enable uniform application of force during high-speed pick operations while remaining within a safe operating range for the actuator.

Referring back to FIG. 1, the test handler 10 may be a high-capacity test handler. For example, a high-capacity test handler with a single T-tray may hold, e.g., 256 DUTs (e.g., DUT 200 of FIG. 2A) or more. There may be two T-trays (e.g., T-tray 250 of FIG. 2A) transported through the various functional areas of the test handler 10 at the same time, including the test area 25, such that as many as 512 DUTs may be tested at a time. Within the T-tray area 15, the T-trays that have been loaded with DUTs may be rotated from a horizontal orientation to a vertical orientation for more efficient transport through the handler and for interfacing with the test system.

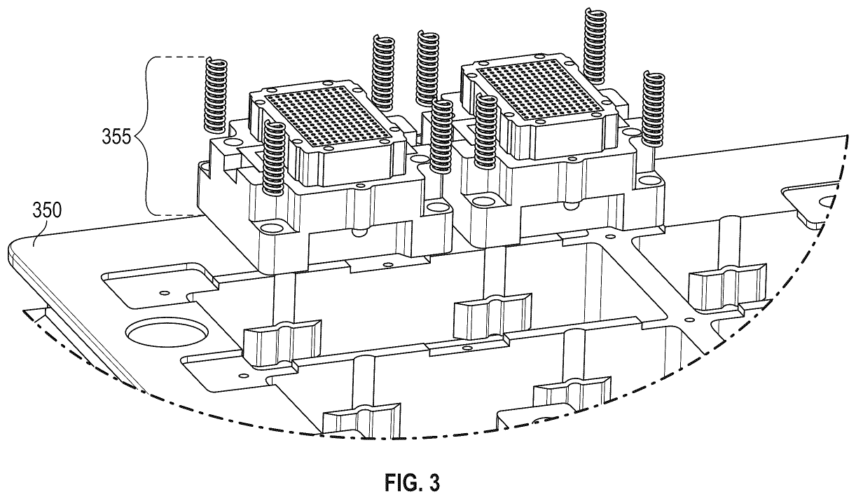

FIG. 3 illustrates further details of exemplary T-trays 350 in an exploded view, according to some embodiments. In some embodiments, T-trays 350 may be similar to T-trays 250 of FIG. 2A. There may be a plurality of carriers 355 that are held within a T-tray 350. While FIG. 3 shows two carriers 355, examples of the disclosure may include any number of carriers 355 including more than two. Each carrier may hold a DUT (not shown in FIG. 3). In some embodiments, there may be a one-to-one correspondence between the number of carriers 355 in a T-tray 350 and the number of DUTs in that T-tray 350. That is, the number of carriers 355 may be the same as the number of DUTs in a T-tray 350.

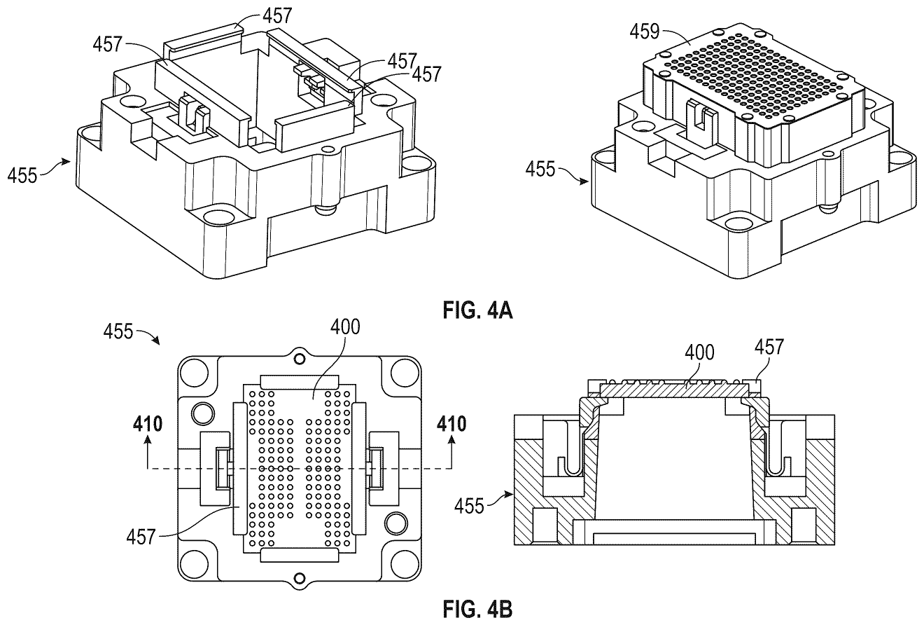

FIG. 4A illustrates details of exemplary carriers 455, according to some embodiments. Carriers 455 may be similar to carriers 355 of FIG. 3. FIG. 4A illustrates example structures that may control the position of a DUT (not shown) within carrier 455. Carrier 455 may comprise ledges 457 that may be built into (e.g., integrated) carrier 455. A surface of a DUT may press against the ledges 457 to provide control of the position of the DUT within the carrier 455. The carrier 455 may comprise a floor 459 that may be configured to control the position of the DUT in two orthogonal directions. For example, floor 459 may control the position of the DUT in the Z-direction and in an X-Y plane. The floor 459 may have features that correspond to features on the DUT that allow for positioning of the DUT on a plane (e.g., an X-Y plane). For example, floor 459 shown in FIG. 4A may have a plurality of holes that correspond to balls on the package of a DUT (e.g., the balls illustrated on DUT 200 as shown in FIG. 2A). Using floor 459 may provide the advantage of locating the DUT by the features that may physically touch the contacts on sockets of a load board (e.g., the sockets 240 of load board 255 of FIG. 2A).

FIG. 4B illustrates further details of carriers 455 and how the DUTs 400 may be positioned within carriers 455, according to some embodiments. FIG. 4B illustrates a plan view of a DUT 400 positioned within carrier 455 and a section view, along the section line 410, of carrier 455 with ledges 457 and a DUT 400 held in place against the ledges 457. The carrier 455 may comprise ledges 457. The DUT 400 may comprise a ball grid array (BGA) package. The interior space of the carrier 455 may contain a cavity, such that the backside of the DUT 400 may be contacted.

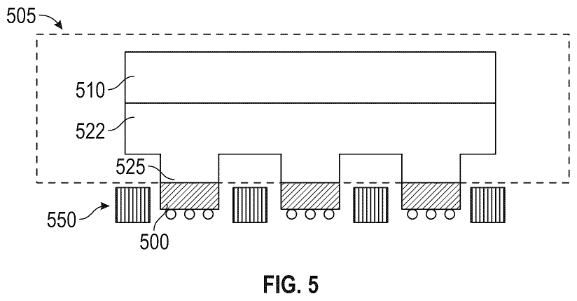

FIG. 5 illustrates an exemplary conductive soak plate assembly 505 that may be utilized in pre-soak area 20 or de-soak area 30 of FIG. 1, according to some embodiments. Conductive soak plate assembly 505 may comprise a global temperature control of the whole soak plate 522. The global temperature control may be provided by a heat exchanger assembly (HEA) 510. The soak plate 522 may have protrusions 525 in each location where there is a DUT 500 in the T-tray 550. The protrusions 525 of the soak plate 522 may extend through the cavities in carriers (e.g., cavities of carriers 455 of FIGS. 4A and 4B, not shown), which may allow the protrusions to directly contact the backside of the DUTs 500. Heat transfer may proceed by conduction from the soak plate 522 through its protrusions 525 to the DUTs 500.

A soak plate 522 used in the pre-soak area 20 may be similar to (e.g., including identical to) a soak plate 522 used in the de-soak area 30. The temperature of the soak plate 522 may be adjusted by changing the temperature or flow rate of a fluid flowing through the HEA 510 attached to or adjacent to the soak plate 522. The adjustment of the soak plate 522 temperature may be controlled by the thermal controller 40 of FIG. 1. In some embodiments, the temperature in the pre-soak area 20 may be set at the first test temperature that will be encountered in a test area (e.g., test area 25 of FIG. 1). In some embodiments, the temperature of the soak plate in the de-soak area 30 may be set such that the temperature of the DUTs 500 is returned to room temperature as quickly as possible. The temperature of the soak plate 522 in the de-soak area 30 may be hotter or colder than surrounding mechanisms, depending on the temperature the DUTs 500 experienced during the last test in the test area. In some embodiments, instead of using a soak plate 522 in the de-soak area 30 with conduction heat transfer, convection heat transfer may be used to change the temperature of the DUTs 500 in the de-soak area 30. Having the surrounding mechanisms at more moderate temperatures and away from test temperature extremes is a significant advantage versus the incumbent chambered solutions that also encompass surrounding mechanisms.

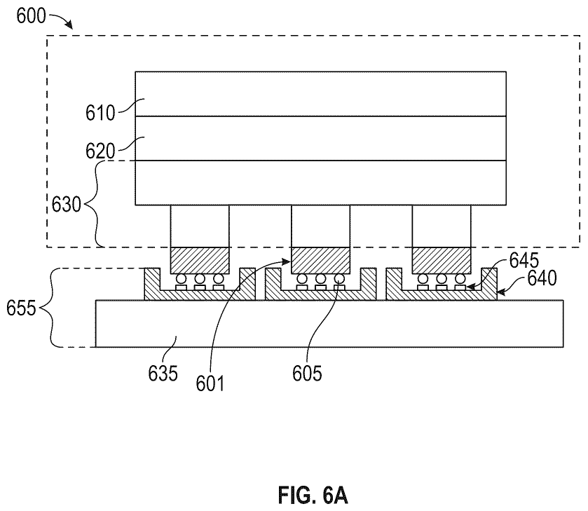

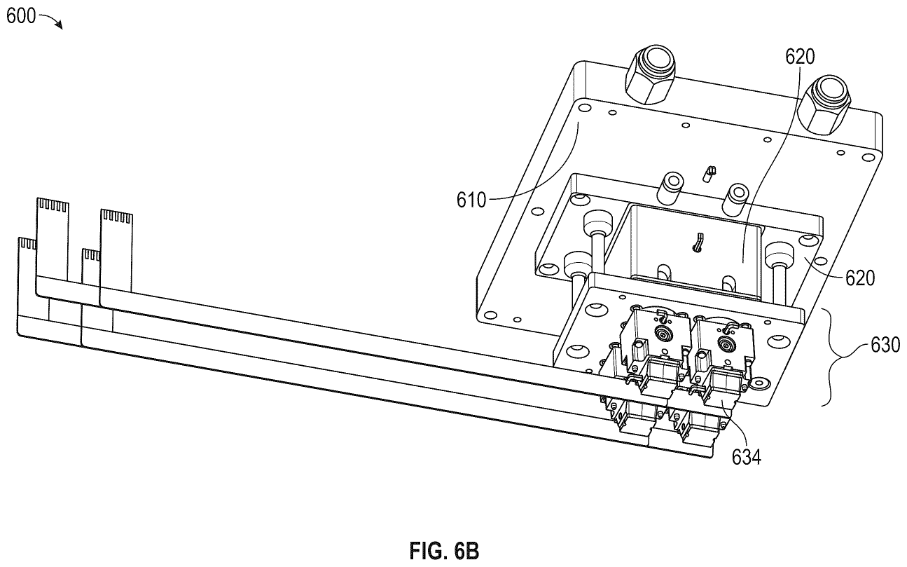

FIG. 6A illustrates a conceptual schematic of thermal head 600, according to some embodiments. Thermal head 600 may be a part of a test handler (e.g., test handler 10 of FIG. 1) and may reside in a test area (e.g., test area 25 of FIG. 1). Thermal head 600 may provide a socketing force on the DUTs 601 so that they properly engage (e.g., have good electrical contact) with the sockets 640 on the load board 655. The thermal head 600 may also enable heating or cooling of the DUTs 601 such that a thermal controller (e.g., thermal controller 40 of FIG. 1) may change or maintain the temperature of the DUTs 601 to be within a targeted range of a set point temperature during testing.

FIG. 6A further illustrates load board 655 that comprises test sockets 640 arranged on a PCB 635, according to some embodiments. The test sockets 640 may include contactors 645. Contactors 645 may comprise pogo pins, elastomeric material, or other structures. FIG. 6A also illustrates DUTs 601, with terminals 605, according to some embodiments. Terminals 605 may be used to make contact between the package of the DUT 601 and another component, such as test socket 640, contactors 645, or a system board in a product (not shown). Terminals 605 may comprise solder balls, leads, land grid array pads or other suitable package terminals 605 as known in the art. FIG. 6A illustrates terminals 605 as solder balls, though it is understood the terminals 605 may be other known suitable package terminals. FIG. 6A further illustrates how terminals 605 may be in contact with the contactors 645 while the DUT 601 is being tested, according to some embodiments.

Thermal head 600 may comprise an HEA 610, a piston block assembly (PBA) 620, and a match plate assembly (MPA) 630. The thermal head 600 may be configured to interface with multiple DUTs 601 at the same time. For example, the thermal head 600 may be configured to interface with four DUTs 601 or eight DUTs 601 at the same time. Thermal head 600 may be configured such that the HEA 610 and the PBA 620 may be designed for universal use and may not be changed out of the test handler very often, while the MPA 630 may be designed specifically for the particular DUTs being tested. In this manner, the HEA can operate as an integrated heat exchanger within the thermal head architecture. The MPA 630 may be used to configure the thermal head 600 both geometrically and functionally for a particular set of DUTs 601. Geometrically the MPA 630 may have protrusions (e.g., pusher blocks and pedestals to be described below) that may be sized to interface with the DUTs 601 (e.g., the protrusions may be about the same size as the top surface of the DUTs 601) and may be located positionally so that they align with the positions of the DUTs 601. Functionally, the MPA 630 may comprise heaters (described below) whose power output may be determined so that they may heat and maintain the temperature of the DUTs 601 at the highest required test temperature. The MPA 630 may change out of the test handler and be replaced by a different MPA 630 at any time, for example, when there is a difference in the DUTs being tested.

Thermal heads 600 can be grouped together in a larger assembly such that a group of thermal heads 600 may be configured to interface with a large number of DUTs 601 at the same time. For example, thermal heads 600 may be configured to interface with 128 DUTs 601 or 256 DUTs 601 or 512 DUTs 601. Being able to interface with a large number of DUTs 601 at the same time may make the overall DUT testing system more productive, efficient, or low cost.

FIG. 6B illustrates an exemplary thermal head 600 that comprises an HEA 610, a PBA 620, and an MPA 630, according to some embodiments. The HEA 610 may comprise a liquid-cooled cold plate, a cooling medium, a Peltier device, a heat exchanger, or any other thermal control device that may be used to adjust the temperature of the HEA 610. A cooling medium within the HEA 610 may comprise air cooling, refrigerant cooling, liquified nitrogen, plant chilled water, or any other suitable medium for lowering the temperature of the HEA 610. While FIG. 6B shows one HEA 610 coupled with one PBA 620, which in turn has an MPA 630 with four pedestals 634, the configuration could be different from what is shown. For example, a thermal head 600 may have one or more HEAs 610, one or more PBAs 620, and one or more MPAs 630 with one or more pedestals 634.

In some embodiments, the HEA 610 may receive a temperature-conditioned cooling medium from an internal chiller subsystem integrated within the test handler. The internal chiller may include one or more heat exchangers configured to remove heat from a closed-loop coolant (e.g., hydrofluoroether (HFE) and/or Thermasolv™ IM7) using a primary refrigerant such as liquid nitrogen (LN₂). In such configurations, the internal chiller may circulate the coolant through a reservoir, pump, manifold, and/or a plurality of proportional flow-control valves configured to direct the coolant to one or more cold plates of the HEA. By supplying a precisely conditioned coolant to the HEA, the internal chiller may enable rapid removal of heat from the PBAs 620, thereby allowing the thermal head 600 to achieve fast temperature transitions, improved thermal stability during DUT testing, and/or enhanced uniformity across a plurality of thermal zones. In some embodiments, the HEA 610 may alternatively receive coolant from another cooling source, such as an external chiller or facility cooling loop, depending on system configuration or thermal load.

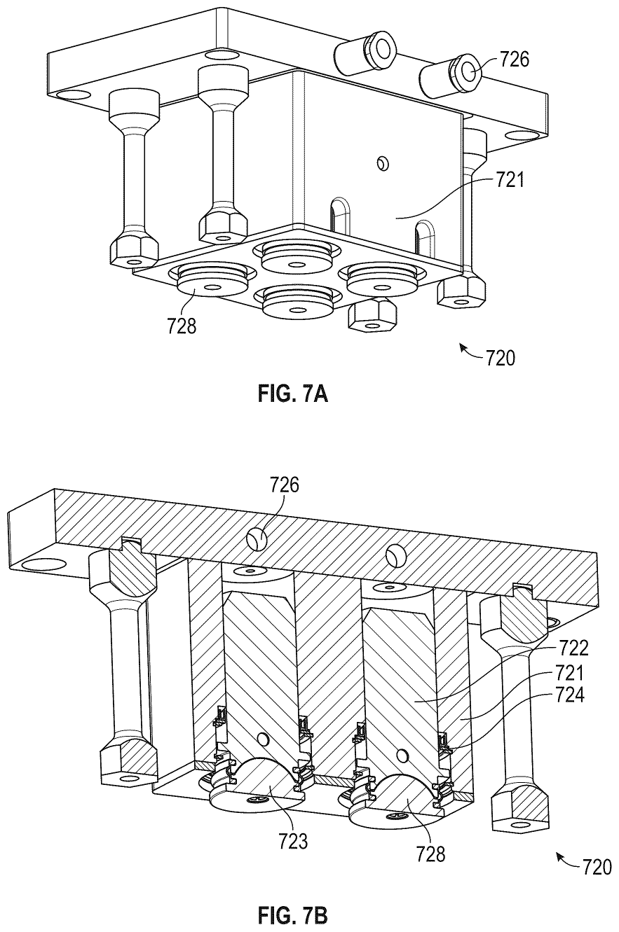

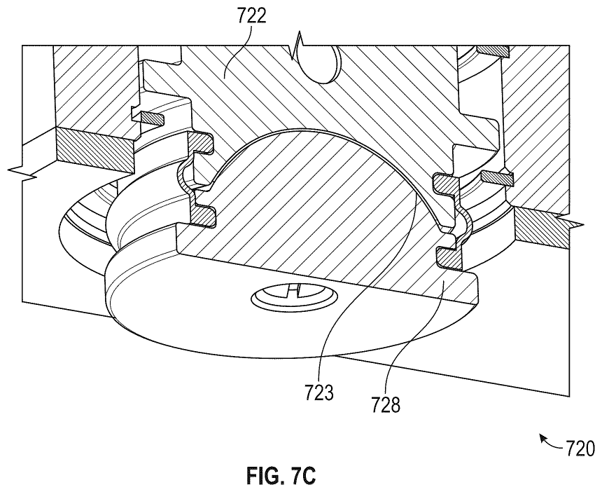

FIGS. 7A and 7B illustrate a piston block assembly (PBA) 720 and a portion of a PBA 720 in a cross-section view, respectively, according to some embodiments. PBA 720 may be similar to PBA 620 of FIGS. 6A and 6B. The PBA 720 may create a uniform force (which may be independent of distance) that may be applied to a DUT (not shown) to push the DUT into a socket (e.g., socket 240 of load board 255 of FIG. 2A, not shown). This may allow for good electrical contact between a DUT and a socket. The PBA 720 may also be used to create a force that can be applied to elements of an MPA (e.g., MPA 630 of FIGS. 6A and 6B). This may allow for the elements of the MPA to be in close physical contact with a DUT, such that heat may be transferred to and/or from the DUT through the MPA.

The PBA 720 may comprise a piston block 721, a piston 722, and a seal ring 724. PBA 720 may comprise port 726 that may supply a gas under a controlled pressure to cause the piston 722 to extend from the piston block 721 or retract into the piston block 721. In some embodiments, the controlled gas pressure supplied through port 726 may be adjusted to directly regulate a socket force applied to each individual DUT during insertion into its corresponding test socket. This programmable socket force capability may be user-selectable (e.g., via a system software interface and/or by manual adjustment of a pressure-regulating device) thereby allowing an operator and/or controller to set a desired force for each DUT independently. By permitting programable socket force in this manner, the system may accommodate variations in DUT package height, socket characteristics, and/or mechanical tolerances while maintaining consistent and repeatable contact force during DUT engagement. A lubricant (not shown), such as grease, may be dispersed between piston 722 and piston block 721. This lubricant may not only function to lubricate the piston 722 but may also be a means to improve heat transfer from the piston 722 to the piston block 721. The PBA 720 may also comprise a pivot 728 with a curved surface that may match a complementary curved surface on the piston 722. This configuration of adjacent curved surfaces may allow for rotation of pivot 728 to accommodate coplanarity issues within an overall thermal head (e.g., thermal head 600 of FIGS. 6A and 6B) or between a thermal head and a DUT.

During operation of the PBA 720 the pressure applied to the pistons 722 may be varied to extend or retract the piston 722. Additionally or alternatively, the pistons 722 may control the force that the piston 722 applies to a DUT. In some embodiments, it may be desirable to have the pistons 722 apply a lower force to the DUTs, such as when first contacting the backside of the DUTs so as not to damage them. In some embodiments, it may be desirable to have the pistons 722 apply a higher force to the DUTs, such as when the DUT is within a socket of a load board and a high force allows for good electrical contact between the DUT and the socket. While FIGS. 7A and 7B depict a PBA 720 with a pneumatic piston 722 to create movement and force, examples of the disclosure are not limited to a pneumatic system. The disclosure herein includes any element that can supply the appropriate force to be used (e.g., a linear motor, a stepper motor, a hydraulic system, or any other known element for supplying force).

FIG. 7C illustrates a closer view of a portion of the piston block assembly 720, including a piston Thermal Interface Material (TIM) 723, according to some embodiments. This piston TIM 723 may improve heat transfer between piston 722 and pivot 728. In some cases, piston TIM 723 may comprise a film that includes carbon-based fillers (e.g., graphite particles or graphene particles). Using a piston TIM 723 comprising carbon-based fillers (e.g., graphite or graphene) may have the additional benefit that graphite is self-lubricating, which may allow pivot 728 to move easily in relation to piston 722. In some embodiments, the TIM 723 may comprise thermal grease, helium gas, air, vacuum, specialty coatings, or other means to improve the heat transfer between piston 722 and pivot 728. A gasket may be used to contain the TIM 723 within a desired area or location, or to prevent debris or particles from entering TIM 723, or an area including TIM 723.

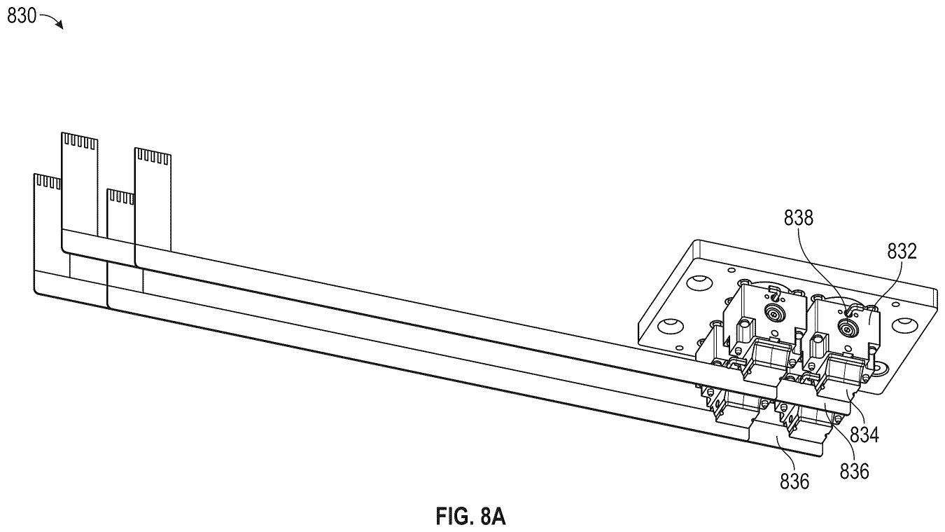

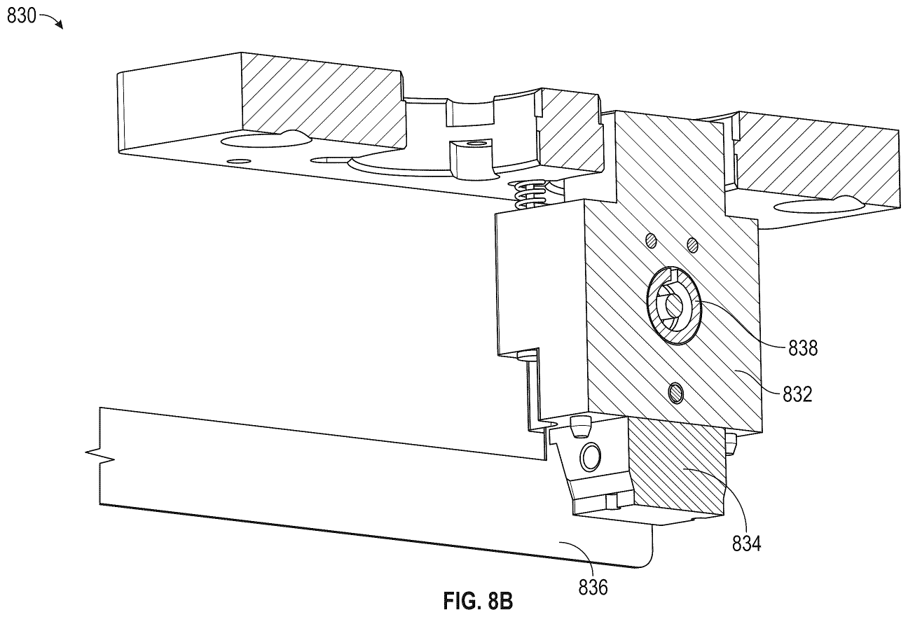

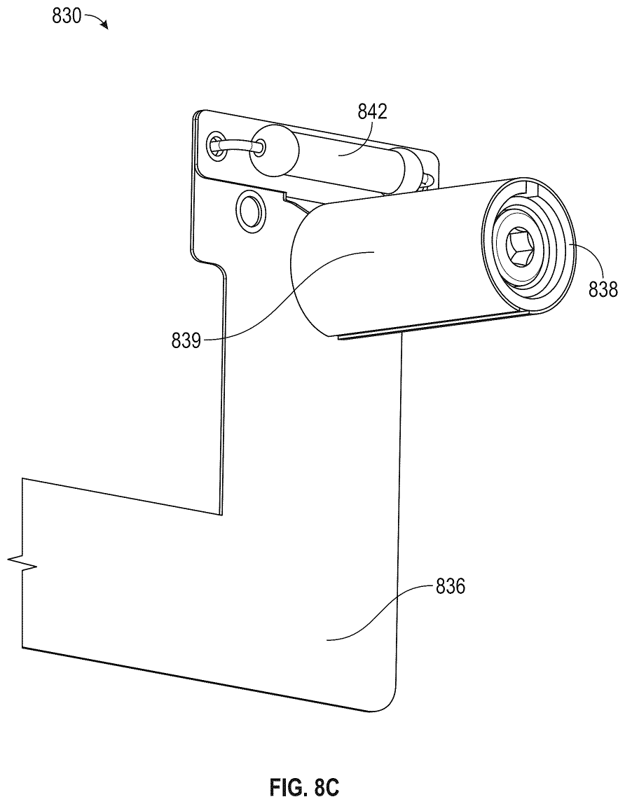

FIGS. 8A-8C illustrate a Match Plate Assembly MPA 830, according to some embodiments. FIG. 8B is a sectional view of a portion of the MPA 830, according to some embodiments. FIG. 8C is a view of MPA 830 with some of the components removed (for purposes of simplifying the illustration and description only), according to some embodiments. In some embodiments, MPA 830 may be similar to MPA 630 of FIGS. 6A-6B.

The MPA 830 may comprise pusher blocks 832, pedestals 834, flex film heaters 836, and mandrels 838. Pusher block 832 may be configured such that a piston or a pivot (e.g., piston 722 or pivot 728 of FIGS. 7A-7C) can exert force on it, which may cause it to move. Pedestal 834 may be affixed to pusher block 832. In some embodiments, there may be a TIM between pusher block 832 and pedestal 834. Pedestal 834 may be configured with a size that is substantially similar (e.g., matches) to a given DUT, such that when a different DUT is to be tested, pedestal 834 may be changed to a more complementary sized or shaped pedestal 834. Flex film heater 836 may comprise a dielectric film and conductive traces. The conductive traces may have a portion configured as a resistor so that current passed through the conductive traces can produce heat. By passing current through the portion of flex film heater 836 configured as a resistor, the flex film heater 836 may heat the pusher block 832, and in turn the pusher block 832 may heat the pedestal 834. The heating of the pedestal 834 through the heating of the flex film heater 836 and the cooling of the pedestal through the cooling of an HEA (e.g., HEA 610 of FIGS. 6A-6B) may be coordinated by a thermal controller (e.g., thermal controller 40 of FIG. 1) to achieve a desired temperature (e.g., at or near a set point temperature) for a pedestal 834 or for one or more (e.g., all) the pedestals 834 of a thermal head (e.g., thermal head 600 of FIGS. 6A and 6B).

The flex film heater 836 may include traces 839 that, in one thermal control period, may act as heaters, but in another thermal control period may act as temperature sensors. The flex film heater 836 may act as a temperature sensor through the association of the resistance of traces 839 of flex film heater 836 with a pre-determined calibration curve correlating the resistance to temperature. This type of arrangement may be referred to as an Integrated Heater and Measurement (IHM) device. In some embodiments, the traces 839 of the flex film heater 836 may comprise a material with a high temperature coefficient of resistance (TCR). On the distal end of the flex film heater 836, a dielectric film and traces may be configured such that they may be easily inserted into an electrical connector, such as a zero insertion force (ZIF) connector with a locking mechanism or a low insertion force connector (LIF), or other suitable connector as known in the art. The connector may be on a printed circuit board assembly (PCBA) that may provide power to the flex film heater 836. In some embodiments, the PCBA may comprise one or more demultiplexer/multiplexer (demux/mux) elements. In some embodiments, the PCBA may be connected to one or more other PCBAs comprising one or more demultiplexer/multiplexer (demux/mux) elements.

At the end of the flex film heater 836 adjacent to the pusher block 832, there may a portion of the flex film heater 836 that may include the resistive heating traces 839. This portion of the flex film heater 836 with the resistive heating traces 839 may be in contact with a sizeable surface area of the pusher block 832. One method to maintain this contact may be to wrap the portion of the flex film heater 836 with the resistive heating traces 839 of the flex film heater 836 around a mandrel 838 and expand the mandrel 838 within a hole formed in the pusher block 832. Mandrel 838 may be positioned within a hole in pusher block 832. By expanding the mandrel 838 within the hole, the portion of the flex film heater 836 with the resistive heating traces 839 of the flex film heater 836 may be pressed tightly against the pusher block 832, maximizing the ability to transfer heat from the flex film heater 836 to the pusher block 832. The mandrel 838 may be expanded in the hole by tightening a tapered screw within an interior hole in the mandrel 838 or by other means. An optional thermal fuse 842 may be used to protect the flex film heater 836 from overheating and possibly causing damage to a DUT.

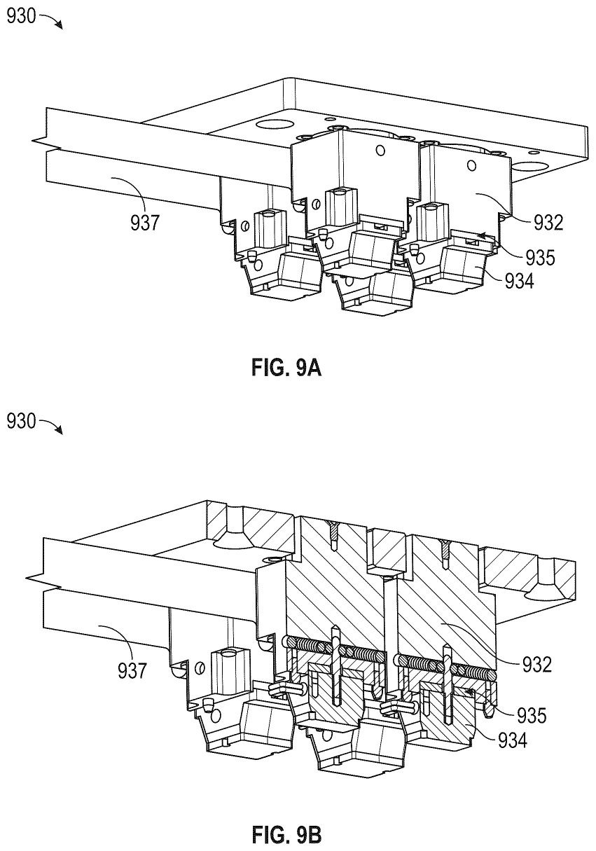

FIGS. 9A and 9B illustrate an exemplary MPA 930, according to some embodiments. FIG. 9A illustrates the MPA, and FIG. 9B illustrates a sectional view of a portion of the MPA 930, according to some embodiments. MPA 930 may comprise a pusher block 932 and a pedestal 934. The embodiment illustrated in FIGS. 9A and 9B may comprise a rigid heater 935 and a flex cable 937. Flex cable 937 may be used to transmit voltages and currents to the rigid heater 935, but may not have traces configured to act as heaters or as temperature measurement devices. The rigid heater 935 may comprise resistor traces that may produce heat when current is passed through them in some portions of a time period (e.g., portions of a first time period). The resistor traces on the rigid heater 935 may be used to determine the temperature of the rigid heater 935 in other portions of a time period (e.g., portions of a second time period). This may be functionally similar and reflective of an IHM device. The rigid heater 935 may comprise insulating materials as a base, metallic materials for traces, and dielectric materials to isolate traces from each other. The insulating and dielectric materials may comprise ceramic, glass, organic, or other materials. There may be one or more layers of traces on the rigid heater 935. In some embodiments, there may be a shield layer included as part of the rigid heater 935. In some examples, TIM may be located between the pedestal 934 and rigid heater 935. Additionally, or alternatively, TIM may be located between rigid heater 935 and pusher block 932.

A thermal head comprising an MPA may comprise heater elements such as a flex film heater (e.g., MPA 830 of FIGS. 8A-8C) or rigid heater (e.g., MPA 930 of FIGS. 9A-9B). In some embodiments, there may be a heater element dedicated to each pusher block and corresponding pedestal, referred to as an active thermal head. An active thermal head may be used to adjust the temperature of each pusher block and corresponding pedestal independently of all the other pusher blocks and pedestals. This may allow the temperature of a DUT being tested to be independently controlled. Embodiments of the disclosure also include a passive thermal head configured with the components disclosed herein, but without a heater dedicated to each pusher block and corresponding pedestal. With respect to a passive thermal head, the temperature of the pusher blocks and corresponding pedestals may be determined by the temperature of an HEA.

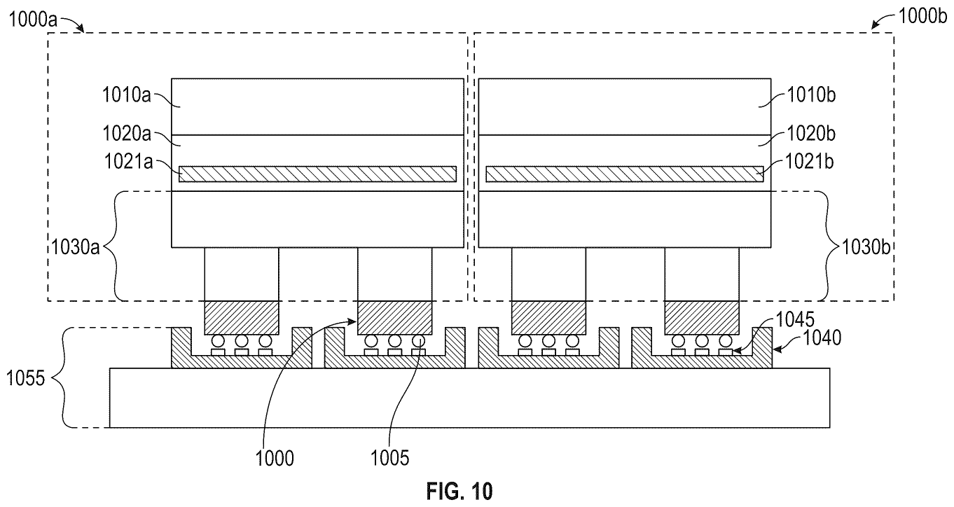

FIG. 10 illustrates a conceptual schematic of an embodiment of thermal heads 1000a and 1000b with Grouped Thermal Control (GTC), according to some embodiments. The figure illustrates terminals 1005 on the packages of the DUTs 1000 contacting with contactors 1045 of the test sockets 1040. GTC may comprise a configuration wherein the thermal control is not addressed to each pusher block or each pedestal individually, but rather addresses a group of pusher blocks or pedestals. In one example, there may be an HEA 1010a, a PBA 1020a, and an MPA 1030a associated with a plurality of DUTs 1000 (e.g., the two DUTs on the left of FIG. 10). There may be a second HEA 1010b, a second PBA 1020b, and a second MPA 1030b associated with a different plurality of DUTs 1000 (e.g., the two rightmost DUTs 1000 in FIG. 10). HEA 1010a and HEA 1010b may be optimized for cooling, while PBA 1020a and PBA 1020b may include heaters 1021a and 1021b, respectively. With this configuration, thermal control by both heating and cooling may be applied to a group or plurality of DUTs 1000 that is less than the full complement (e.g., total number of DUTs 1000 in the T-tray 1055). As an example, one GTC configuration may comprise four HEAs (such as HEA 1010a and 1010b of FIG. 10) each coupled to a PBA (such as PBA 1020a and 1020b of FIG. 10) with a heater, which in turn may be coupled to an MPA (such as MPA 1030a and 1030b of FIG. 10) configured to contact a plurality of DUTs, such as 64 DUTs per MPA. This GTC configuration may address 256 DUTs in total (64 DUTs per MPA multiplied by four HEA/PBA/MPA assemblies). In this example, thermal control (heating, cooling, or both) may be applied to four different groups of 64 DUTs. In some embodiments, different configurations other than the one described here, e.g., comprising four HEA/PBA/MPA assemblies each contacting with 64 DUTs may be used for GTC. In some cases, an HEA may be configured to couple with two or more groups of PBA/MPA assemblies. In some cases, the heaters coupled with the PBAs (such as heaters 1021a and 1021b of FIG. 10) may comprise IHM elements that are capable of both heating and measuring temperature.

Thus, the systems disclosed herein can support both Active Site Control (e.g., corresponding to individually addressable heater elements) that can regulate temperature at each DUT location independently, and Active Group Control, (e.g., corresponding to the grouped thermal control (GTC) architecture) in which subsets of DUTs share combined heating and/or cooling resources.

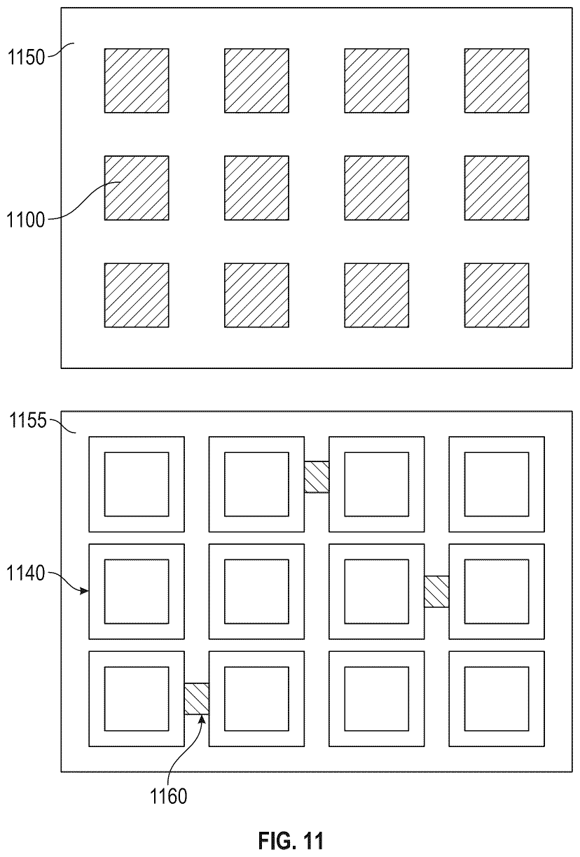

FIG. 11 illustrates a T-tray 1150 loaded with DUTs 1100, according to some embodiments. A load board 1155 may include test sockets 1140. The pitch and location of DUTs 1100 in the T-tray 1150 matches the pitch and location of the test sockets 1140 on the load board 1155. Additionally, there may be components 1160 on the load board 1155 that comprise part of the circuitry of the load board 1155. In some cases, these components 1160 may dissipate a meaningful amount of heat that may affect the performance of the thermal heads or the uniformity of the temperatures of the pusher blocks or pedestals within the thermal heads.

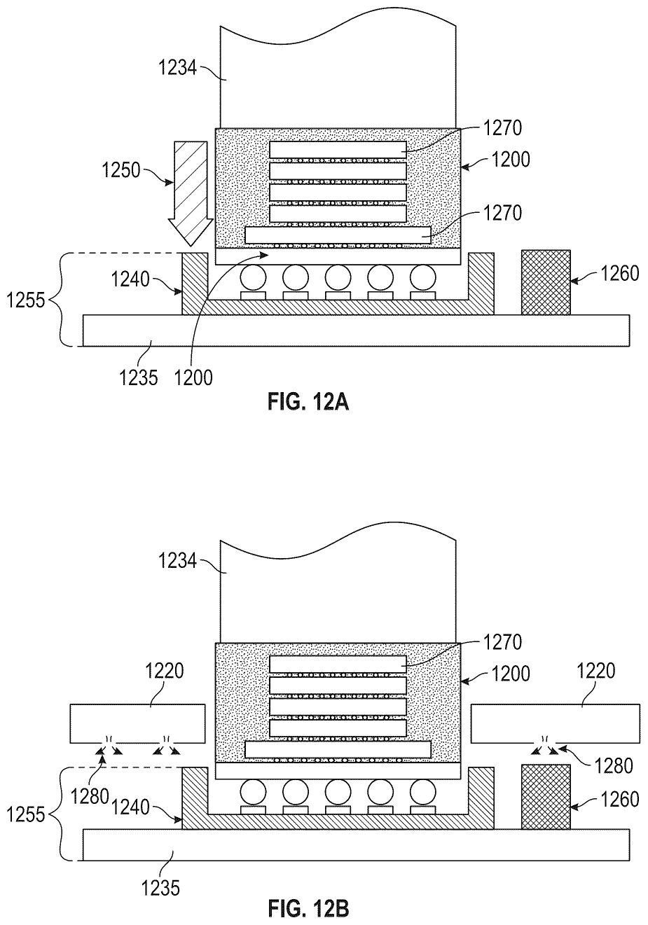

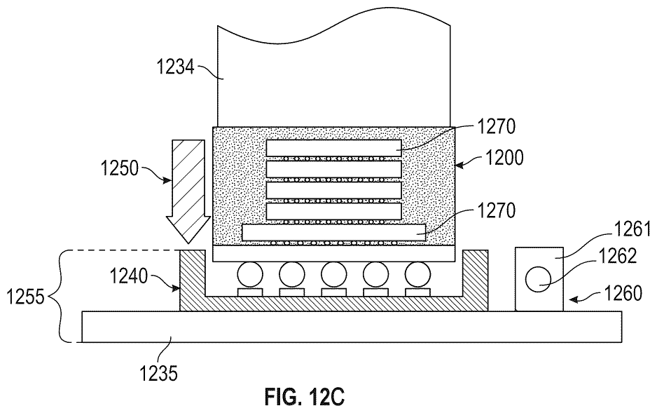

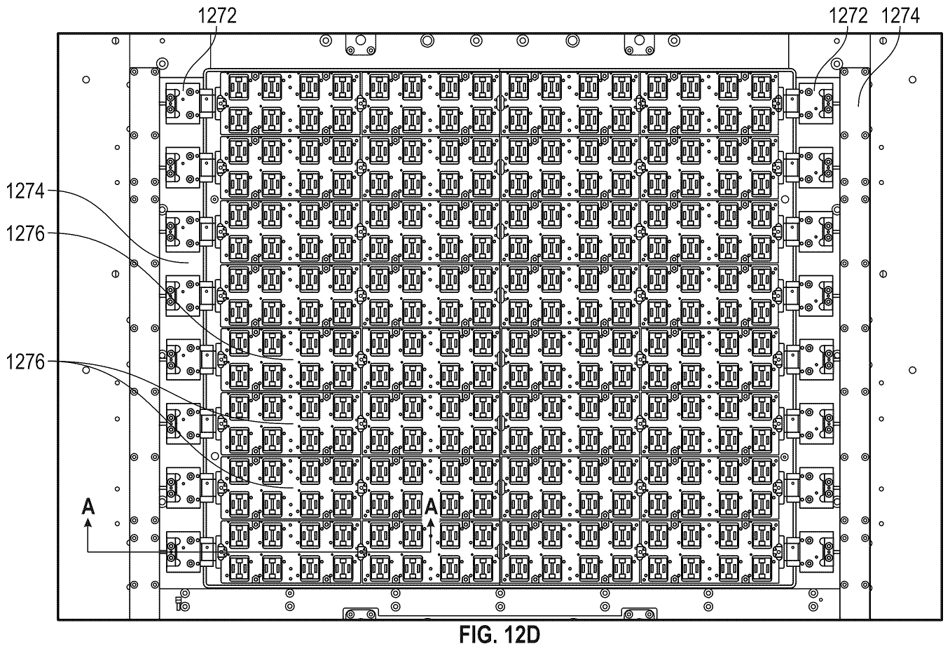

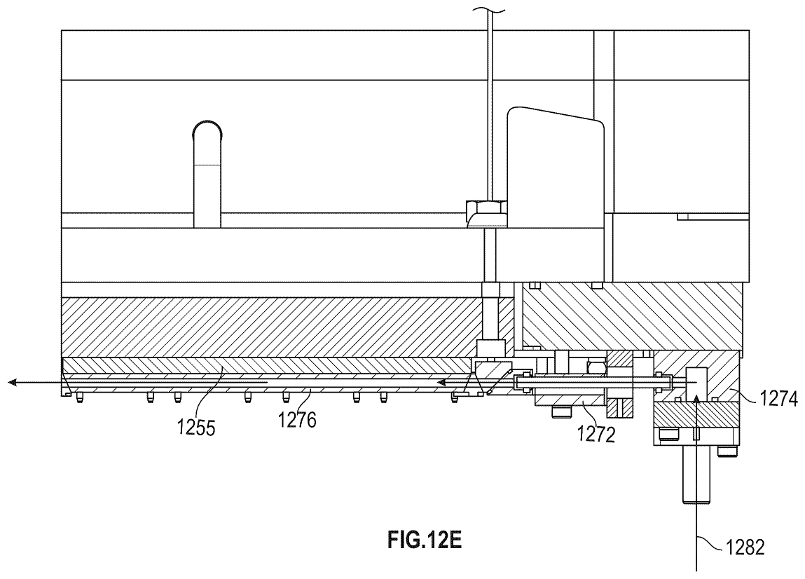

In some embodiments, such thermal non-uniformity may be mitigated or controlled through convective and/or conductive temperature conditioning structures. For example, a system of convective flow channels may be used to direct temperature conditioned air toward selected regions of the load board or components mounted thereon, thereby reducing localized hot spots or cold regions. Such convective temperature-control approaches are described in further detail with respect to FIG. 12B. Additionally or alternatively, a thermally conductive frame coupled to the PCB and incorporating internal fluid channels may be used to actively heat or cool regions of the load board, thereby improving board-level temperature uniformity. Such conductive temperature-control approaches are described in further detail with respect to FIG. 12C.

FIG. 12A illustrates a cross-section view of an example DUT 1200 coupling with the socket 1240 on the PCB 1235 of a load board 1255, according to some embodiments. Load board 1255 may comprise a heat-dissipating component 1260. Depending on the type of device, within the body of the DUT 1200 may comprise a plurality of IC chips 1270, such as in a stacked chip configuration as shown in FIG. 12A. Contacting the backside of the DUT 1200 may be a pedestal 1234 that is part of a thermal head (e.g., thermal head 600 of FIG. 6A-6B, not shown). In some embodiments, because the pedestal 1234 may contact only one side of the DUT 1200, the heat transfer to and/or from the pedestal 1234 to the DUT 1200 may be different than the heat transfer from the DUT 1200 to the socket 1240 or the load board 1255. Because of the different rates of heat transfer from the backside of the DUT 1200 versus the frontside of the DUT 1200, a temperature gradient may develop across the DUT 1200. The arrow labeled 1250 is intended to depict a potential thermal gradient across the DUT 1200. A temperature gradient across DUT 1200 may mean that the temperatures of the IC chips 1270 within the DUT 1200 may be different from each other. It may be desirable to try to minimize the temperature gradient across a DUT 1200. It may be also desirable to minimize the temperature non-uniformity of the load board 1255 caused by heat-dissipating components 1260.

FIG. 12B illustrates a load board 1255 with a socket 1240 located on a PCB 1235, DUT 1200, pedestal 1234, and convective flow channels 1220, according to some embodiments. Convective flow channels 1220 may carry temperature conditioned air to different areas of the load board 1255. Openings in the flow channels 1220 may provide shower locations 1280 where the temperature conditioned air can be directed onto the load board 1255 or elements on the load board 1255 such as sockets 1240, DUTs 1200, or heat-dissipating components 1260. The temperature of this conditioned air and specific location of impingement may be tailored and optimized per application. The implementation of such capability may be agnostic to the type of socket 1240 used or DUT 1200 test temperature setpoint. Using flow channels 1220 and shower locations 1280 may alleviate the temperature differences across the load board 1255 and the temperature gradient across the DUTs 1200.

While FIG. 12B illustrates the flow channels 1220 as independent elements, they may be coupled to or incorporated with other elements of a test handler (e.g., test handler 10 of FIG. 1). For example, the flow channels 1220 may be incorporated into socket guide plates that are used within a test area (e.g., test area 25 of FIG. 1) to properly align DUTs 1200 to the sockets 1240. In this fashion, the flow channels 1220 may comprise a portion of a standard part of a test handler and there may be no need to install new hardware in the test area to accommodate the cooling function provided by the flow channels 1220.

In addition to or alternatively to the convective temperature-control approaches described with respect to FIG. 12B, the temperature of the load board 1255, sockets 1240, and associated components may additionally or alternatively be controlled through conductive means. FIG. 12C illustrates an embodiment in which a thermally conductive frame incorporating internal fluid channels is used to adjust the temperature of the PCB and/or other components.

For example, FIG. 12C illustrates a load board 1255 with a socket 1240 located on a PCB 1235, DUT 1200, pedestal 1234, and heat-dissipating components 1260, according to some embodiments. In some embodiments, heat-dissipating components 1260 can comprise a fluidic-based temperature-control mechanism formed by thermally conductive frame 1261 and internal fluid channel(s) 1262. Temperature control of the load board 1255, socket 1240 and/or other associated components can also be affected via conductive means. For example, thermally conductive frame 1261 with internal fluid channel(s) 1262 may be attached to the PCB surface. The thermally conductive frame 1261 can comprise a metal material. For example, the thermally conductive frame 1261 can comprise a metal or metal alloy such as aluminum, copper, stainless steel, alloys thereof, or other thermally conductive materials. The fluidic channel(s) 1262 can be filled with a temperature conditioned fluid. For example, the fluid can comprise air, clean dry air, nitrogen gas, other gases, water, glycol-based coolant, dielectric cooling fluid, refrigerant, combinations thereof, or other suitable heat-transfer fluid. The temperature of fluid within internal fluid channel(s) 1262 can be varied. As the temperature of the fluid changes, the thermally conductive frame 1261 can correspondingly change temperature and can be used to raise or lower the temperature of the PCB 1235. Because PCBs generally include copper in their electrical traces, the resulting thermal resistance between the frame 1261 and PCB-mounted structures can be low. The low thermal resistance can allow the heating or cooling effect from the thermally conductive frame 1261 to be efficiently transferred to the sockets 1240, components 1260, and other PCB-mounted elements.

In some embodiments, the fluid-based conductive temperature-control mechanism described with respect to FIG. 12C may be used concurrently with convective flow channels, thermal heads, and/or other temperature-control components to achieve desired thermal profiles during DUT testing.

In some embodiments, a plurality of the temperature conditioning structures described with respect to FIGS. 12A-12C may be deployed across a larger portion of the load board region to provide distributed thermal conditioning for the DUTs 1200 received by the load board 1255. FIG. 12D illustrates an example in which multiple load board conditioning structures 1276 can be arranged in an array that spans the area over which sockets 1240 are mounted on PCB 1235. A conditioning structure 1276 may incorporate one or more of the convective flow channels 1220 of FIG. 12B, the conductive frame 1261 and internal fluid channel 1262 of FIG. 12C, and/or other temperature control elements described herein. As shown in FIG. 12D, fluid-delivery interfaces 1272 may be provided along opposing sides of the load board region, and each interface 1272 may supply temperature conditioned fluid to one or more rows of conditioning structures 1276. A fluid distribution manifold 1274 may extend along each side of the load board region and may deliver conditioned fluid to the various interfaces 1272, enabling uniform distribution across a large number of conditioning structures.

FIG. 12E illustrates a cross-sectional view (Section A-A) of the internal fluid-delivery arrangement shown in FIG. 12D. As shown, temperature conditioned fluid may be routed through an internal fluid flow path 1282 formed within the handler frame to the fluid distribution manifold 1274. The manifold 1274 may provide the fluid to a corresponding fluid delivery interface 1272, which may in turn supply the fluid to one or more load board conditioning structures 1276 positioned adjacent to the load board 1255. Each conditioning structure 1276 may thereby receive conditioned fluid sufficient to cool or heat the corresponding portion of the load board 1255, the sockets 1240, and/or nearby components. In this manner, the internal routing of temperature-conditioned fluid may service multiple instances of the temperature-control structures described with respect to FIGS. 12A-12C, scaled across an array of DUT sites.

Delivering conditioned fluid internally through the handler may provide several advantages. Because the load board conditioning structures 1276 are supplied by internal manifolds and fixed fluid delivery interfaces, there may be no need for external fluid connections to attach directly to the load board 1255 itself. This configuration may simplify load board exchange, reduce mechanical complexity, and/or decrease the risk of fluid leakage. In some embodiments, the temperature conditioned fluid may be generated within the handler, whereas in other embodiments the fluid may be conditioned externally and routed through the handler to the conditioning structures 1276. The combination of internal fluid routing and distributed conditioning structures may improve the thermal uniformity of the load board region and may allow both convective and conductive temperature control mechanisms to be applied concurrently or in a complementary fashion.

In some embodiments, the load board conditioning structures 1276 may receive temperature-conditioned air generated by an internal chiller subsystem of the test handler. The internal chiller may include a cooling stage in which clean dry air (CDA) is passed through a heat exchanger thermally coupled to a primary refrigerant (e.g., liquid nitrogen), allowing the CDA to be cooled to a controlled temperature before being delivered toward regions of the load board. In some operating modes, the CDA may be routed through a heating stage to raise its temperature for hot-mode conditioning. One or more valves within the chiller subsystem may regulate CDA flow paths during cold and hot operation, including enabling or disabling chilled CDA delivery, directing CDA through heating elements, or diverting CDA for purging or bypass.

Referring back to FIG. 1, the test handler 10 may comprise a bin-out area 35 where tested DUTs are segregated by their test results into different ‘bins’, and DUTs with the same bin category are transferred from the T-trays into JEDEC trays.

FIG. 1 illustrates the test handler 10 comprising thermal controller 40. A thermal controller 40 may independently control the temperature of the individual pusher blocks (e.g., pusher blocks 832 of FIGS. 8A-8C or pusher blocks 932 of FIGS. 9A-9B), or individual pedestals (e.g., pedestals 634 of FIG. 6A, pedestals 834 of FIGS. 8A-8C, or pedestals 934 of FIGS. 9A-9B) in an active thermal head (e.g., thermal head 600 of FIG. 6A), or in groups of active thermal heads. In some embodiments, a thermal controller 40 may control the temperature of an HEA (e.g., HEA 610 of FIG. 6A) to globally control the temperature of pusher blocks or pedestals in a passive thermal head system. In a system with multiple thermal heads, one or more thermal controllers 40 may control the temperature of all the thermal heads. The thermal controller 40 may comprise one or more FPGAs as the processors for the system. The thermal controller 40 may be configured as a plurality of channels that are demultiplexed such that one thermal controller 40 and one power source may supply multiple flex film heaters (e.g., flex film heaters 836 of FIGS. 8A-8C), multiple rigid heaters (e.g., rigid heater 935 of FIGS. 9A-9B), or multiple zones within one or more thermal heads. As an example, one thermal channel may comprise four (4) thermal heads that can dissipate about 250 W. In some embodiments, the thermal controller may also regulate the temperature of conductive load-board structures, such as fluid-cooled or fluid-heated frames (e.g., thermally conductive frame 1261 of FIG. 12C), by controlling fluid temperature, flow rate, or both.

Aspects of the disclosure may comprise systems and methods for applying IHM devices and a thermal control system, such as the IHM system and method disclosed in U.S. Pat. No. 11,828,796 (application Ser. No. 18/311,164), the contents of which are incorporated by reference in its entirety herein. In some examples, the HIM method may comprise demultiplexing (demuxing) of power to heaters and multiplexing (muxing) of heater voltages at a given sense current (to determine heater resistance) to reduce the amount of local wiring associated with independent IHM devices. These methodologies may be important in some applications such as (but not limited to) where there is a large number of DUTs to be tested at one time, such as more than 8 DUTs or more than 32 DUTs. The large number of DUTs may be controlled in temperature during the test period. For example, as previously noted, a test handler (e.g., test handler 10 of FIG. 1) may be configured for parallel testing of a large number of DUTs, such as 512 DUTs. The system may be configured to have two T-trays that each hold 256 DUTs. In a system with active thermal heads, without demultiplexing and multiplexing or without IHM (which may reduce the amount of wiring needed local to the IHM devices (e.g., flex film heaters or rigid heaters)), it may be difficult or not advantageous to support heaters and temperature sensing at each DUT location.

In some embodiments, the test handler may include an internal chiller subsystem that cooperates with the thermal heads and load-board conditioning mechanisms to provide coordinated thermal control during DUT testing. The internal chiller may regulate one or more coolant circuits, such as a closed-loop coolant used to remove heat from temperature-control structures within the handler, and a CDA circuit that may be cooled or heated depending on operating mode. For example, the internal chiller may cool a liquid coolant by passing it through a heat exchanger, and may control coolant flow using pumps, valves, temperature sensors, and flow measurements to maintain the coolant within a desired temperature range. In addition, the internal chiller may condition CDA for use in load-board temperature management by cooling the CDA using a refrigerant and/or by directing the CDA through a heating stage during hot-mode operation.

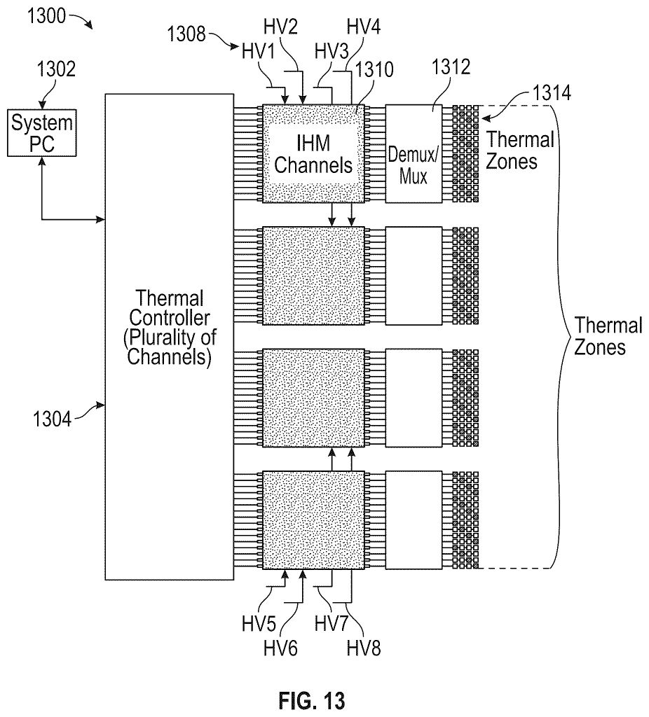

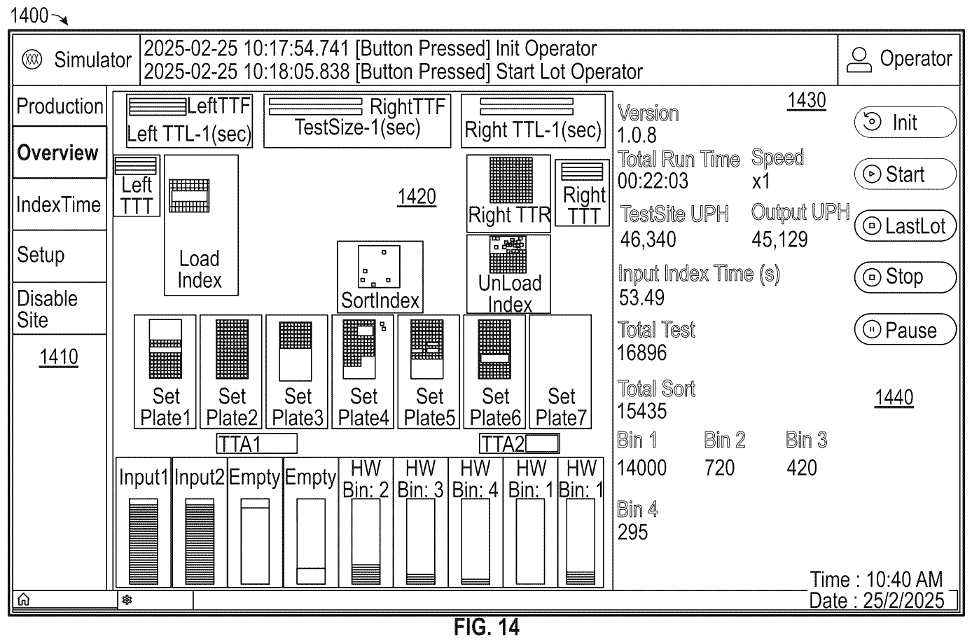

FIG. 13 illustrates a thermal control system 1300, according to some embodiments. FIG. 13 illustrates a thermal control system 1300 for one T-tray (not shown) that would hold associated DUTs, in this case, e.g., 256 DUTs. For example, there may be two T-trays, with each T-tray having 256 DUTs being tested at one time, with a total of 512 DUTs being tested at one time. A system with active thermal heads may possess the ability to supply voltage to heaters (during periods of heating), and supply current to and read the voltage drop across heaters (during periods of temperature sensing by deriving the resistance of the heater) for a total of 512 IHM devices. Each heater may be arranged to heat individual pusher blocks or individual pedestals that couple to each one of the 512 DUTs being tested. The thermal control system 1300 may couple to a system computer 1302.

The thermal control system 1300 may comprise a thermal controller 1304 that may be able to handle a plurality of (e.g., 64) IHM channels. The channels may be divided so that boards 1310 each comprise a plurality of (e.g., 16) IHM channels. Coupled to these boards may be high voltage (HV) sources 1308 for supplying power to heat the IHM devices when they are in a heating mode. A demultiplexer/multiplexer (demux/mux) element 1312 may allow for a multiplicative correspondence between the IM channels and thermal zones 1314. In the example of FIG. 13, there are four thermal zones 1314 (individually selectable at different times) for each RIM channel. A thermal controller 1304 that has 64 IHM channels and a demux/mux element 1312 with a 1:4 multiplicative capability can support access to and control of 256 thermal zones 1314. Two of such thermal control systems 1300 could be controlled by one system computer 1302, to provide individual thermal control of 512 thermal zones 1314, or in other words, control the temperature of 512 DUTs being tested at one time.

FIG. 13 depicts only one of many possible configurations of a thermal control system 1300. For example, the thermal control system 1300 may comprise more thermal controllers 1304 each with fewer or greater channels than shown here. In some embodiments, the configuration of the boards 1310 may comprise less than 16 IHM channels or more. There also may be demux/mux elements 1312 that have a different multiplicative factor other than 1:4, such as 1:2, 1:8, or any other configuration. FIG. 13 depicts the demux/mux element 1312 as one component, but it may comprise multiple separate components, such as a demultiplexer (switching a single power drive between multiple thermal zones 1314) and a multiplexer (switching between multiple thermal zones to supply heater resistance measurements to one channel of the thermal controller 1304). Finally, the thermal control system 1300 may be configured to control less than 256 thermal zones 1314 or more.

For the case of parallel testing of a plurality of DUTs, the goal of the thermal control system 1300 may be to hold the temperature of all the DUTs as close as possible to a set point temperature. Maintaining the DUTs at a desired set point temperature may comprise stepping through the thermal zones 1314 in some sequence and/or adjusting the heating of the thermal zones individually. For example, the thermal control system 1300 may step through all the thermal zones 1314, rapidly determine the temperature of thermal zones 1314, and adjust the power of the IHM element based on the determination. As an example, the thermal control system 1300 may step from one thermal zone 1314 to an adjacent thermal zone 1314 and proceed in this fashion around an area of the T-tray. In some cases, the thermal control system 1300 may determine a different stepping pattern, such as stepping from one thermal zone 1314 to a second thermal zone 1314 positioned at a location far away from the first thermal zone 1314. Another strategy may be to move rapidly from one thermal zone 1314 to another thermal zone 1314 and continuing in this fashion over an area (e.g., the whole area) of the T-tray. This method that might be referred to as rapidly flashing the heaters in each thermal zone 1314. A flashing strategy may benefit from a thermal controller 1304 that can make calculations quickly and has a high frequency of operation, as well as demux/mux elements 1312 that can rapidly switch between thermal zones 1314. In some cases, the thermal controller 1304 may comprise an FPGA. In some cases, the flashing strategy may only address one thermal zone (including heating and temperature sensing periods) for a few hundreds of milliseconds, or in some cases even as quickly as tens of milliseconds.

The DUT handling and a thermal controller (e.g., thermal controller 40 of FIG. 1) may be configured such that a single insert operation of placing the DUTs into sockets of a load board can be used for testing at two or more temperatures. The DUTs coupled to one or more thermal heads (e.g., thermal heads 600 of FIG. 6A) may be tested at a first temperature (e.g., 100° C.), then the thermal controller can adjust the temperature of the thermal heads so that the DUTs may be tested at a second temperature (e.g., 125° C.) different from the first temperature. This may be accomplished with only one insertion operation of the DUTs being inserted into the sockets of the load board.

FIG. 14 illustrates an exemplary graphical user interface (GUI) 1400 of a simulation and analytics environment configured for use with a test handler, according to some embodiments. The GUI 1400 may present a real-time or accelerated visualization of material flow, handler state, and throughput metrics. A navigation panel 1410 may appear along a lateral portion of the display and may include selectable interface categories such as Overview, IndexTime, Setup, and/or DisableSite. A production-flow visualization region 1420 may present schematic representations of one or more transport modules, load indices, test sites, sort sites, unload indices, and/or other components, any of which may dynamically update to reflect DUT occupancy or operational state. In some embodiments, color, shading, patterning, and/or fill levels of these graphical elements may indicate DUT count, test results, processing state, and/or flow across stations.

A metrics panel 1430 may be displayed along another region of the GUI 1400, providing numerical indicators associated with system performance. Such indicators may include a software version identifier, a total run-time indicator, a simulation speed indicator, a test site throughput (UPH) indicator, an output throughput indicator, an input index time measurement, a total test counter, and/or a total sort counter. In some embodiments, the GUI 1400 may further present bin-distribution indicators showing counts of DUTs assigned to respective output bins. An operator-control panel 1440 may be provided to allow initiation, stopping, pausing, or advancement of a simulation or lot sequence.

In some embodiments, the GUI 1400 may further include a throughput-simulation module configured to model handler performance under different operating conditions. The throughput-simulation module may allow a user to simulate units-per-hour (UPH), input-index time, or related timing metrics based on selected handler configurations, change-kit arrangements, and/or DUT population characteristics. In certain implementations, a fast-forward simulation mode may be provided to enable accelerated evaluation of throughput behavior, allowing system behavior over hours of randomized product-yield conditions to be visualized and/or analyzed in a time-compressed manner. The simulation module may also support evaluation of alternative sorting strategies, including scenarios involving high-yield or low-yield operating conditions, site-disable configurations, or multi-site imbalances that may arise during production.

The GUI 1400 may additionally include an optional automated-optimization module configured to analyze production behavior and recommend improved operating parameters. For example, the automated-optimization module may evaluate tray-loading arrangements or DUT-binning characteristics and identify sorting strategies that improve overall throughput. In some embodiments, the system may suggest pick and place arm configurations or handler-motion patterns suited to a particular DUT distribution or lot profile. The optimization module may further incorporate machine-learning or artificial-intelligence components configured to refine sorting behavior over time based on observed production results, allowing the system to adjust or improve performance parameters during continued operation.

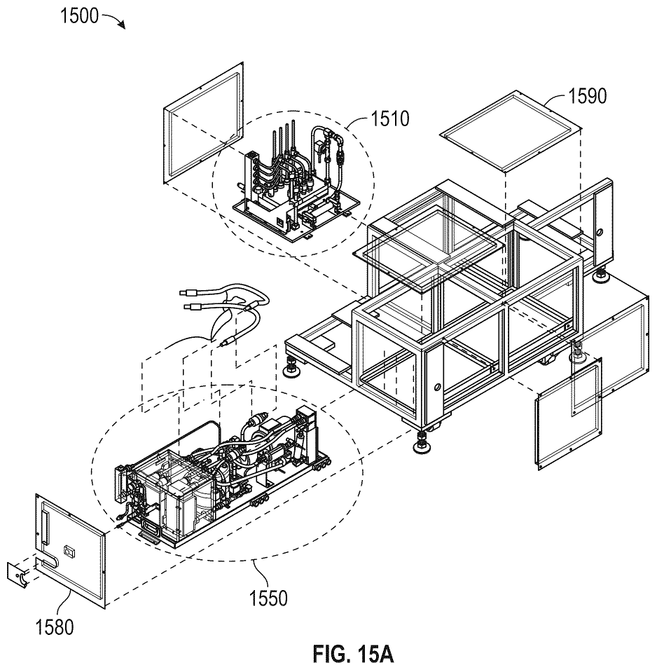

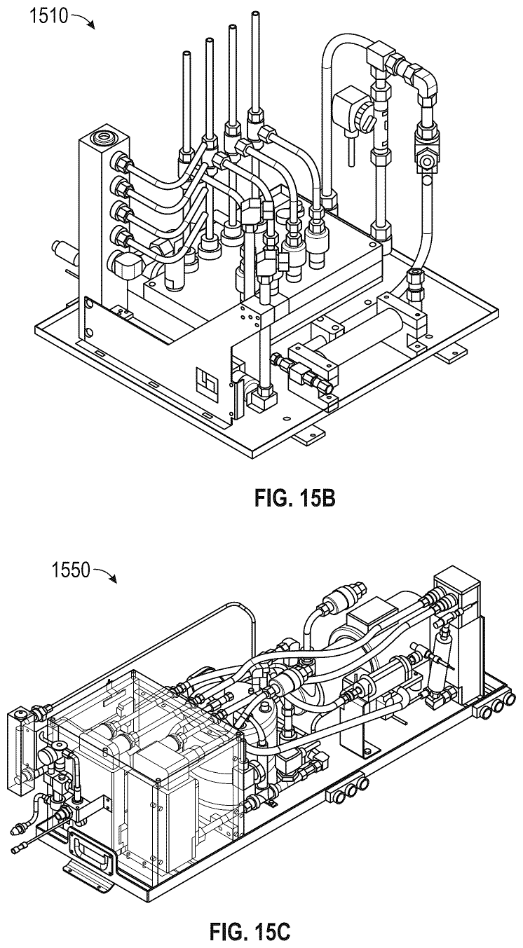

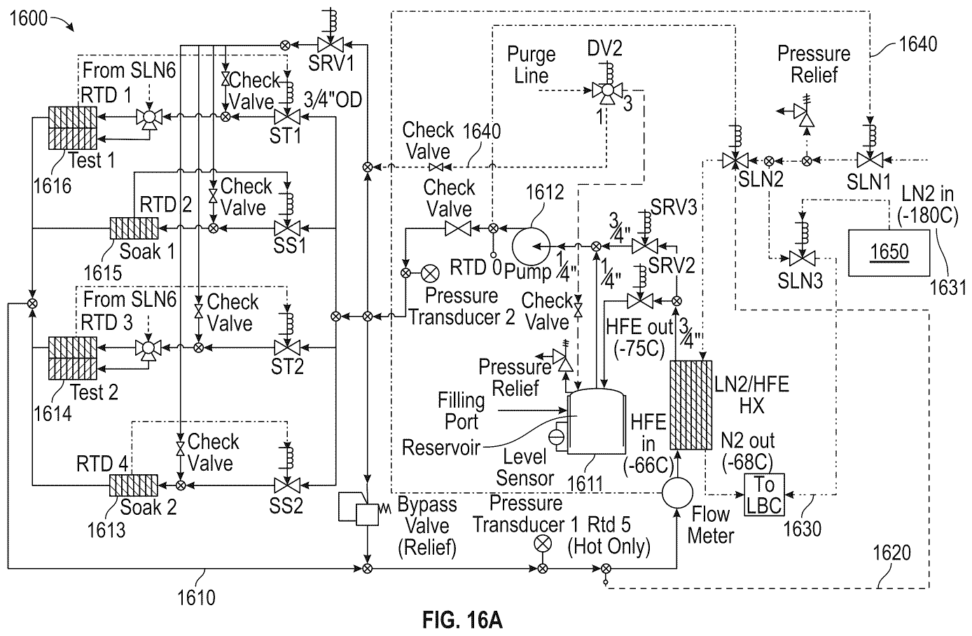

As shown in FIGS. 15A-15C, the test handler may include an internal chiller subsystem 1500 configured to provide temperature-conditioned media used throughout the thermal control architecture of the system. FIG. 15A illustrates an exemplary internal chiller subsystem 1500 integrated into a frame 1590 of the test handler and arranged such that a chiller base assembly 1550 is mounted within a drawer 1580 for ease of access. FIG. 15B illustrates an exemplary manifold module 1510 of the internal chiller subsystem. FIG. 15C illustrates an exemplary chiller base assembly 1550. These components may cooperate to receive, condition, and distribute coolant and CDA to soak plates, thermal heads, and load-board conditioning structures.

The internal chiller subsystem 1500 may support a plurality of different working fluids. For example, the internal chiller subsystem 1500 may provide and control the supply of a primary refrigerant (e.g., liquid nitrogen (LN₂)), an open-loop coolant (e.g., clean dry air (CDA)), and a closed-loop coolant (e.g., Thermasolv™ IM7 and/or hydrofluoroether (HFE)). LN₂ may operate as the primary refrigerant and may supply cooling to one or more internal evaporators (e.g., plate heat exchangers). In some embodiments, an LN₂ supply line may deliver LN₂ to two separate evaporators: a first evaporator configured to cool the IM7 loop, and a second evaporator configured to cool CDA used for load board conditioning (LBC), (e.g., via the LBC temperature-conditioning structures 1276 described with respect to FIG. 12D).

The open loop coolant (e.g., CDA) may be cooled by passing through an LN₂-based heat exchanger within the chiller subsystem 1500, and the cooled CDA may be delivered toward the load board (e.g., load board 1255) to reduce temperature differences between the load board and the thermal heads (e.g., thermal heads 600). In some embodiments, CDA may instead be routed through a heating stage during hot-mode operation, which may help minimize heat losses when the load board is maintained at an elevated temperature. One or more valves of the chiller base assembly 1550 may regulate CDA routing among chilled, heated, and/or bypass flow paths.

The closed loop coolant circuit may be used to remove heat generated during DUT testing. In some embodiments, IM7 may be pumped from a reservoir through a distribution manifold (e.g., manifold module 1510 of FIG. 15B) that separates the coolant into multiple parallel paths supplying downstream temperature control structures, including soak plates such as soak plate 522 shown in FIG. 5, and test plates (e.g., as described with respect to FIG. 5). After removing heat from these plates, the IM7 may return to the chiller base assembly 1550 where it is cooled by the LN₂-based evaporator and brought back to a desired supply temperature setpoint. Once at this setpoint, the IM7 may be recirculated to complete the coolant cycle.

The internal chiller subsystem 1500 may also include sensors and control elements used to regulate temperature and flow conditions within the coolant and CDA circuits. For example, temperature sensors (e.g., resistance thermometers (RTDs)) may provide feedback for adjusting LN₂ valve states, coolant pump speed, and flow-control valve positions. A pump within the chiller base assembly 1550 may be driven by a variable-frequency drive (VFD), and the operating logic may increase or decrease pump speed based on the degree of opening of proportional valves, as described in the chiller control sequences. Such regulation may maintain stable coolant flow to temperature-control elements such as soak plates, thermal heads, and/or load-board conditioning structures.

By supplying temperature-conditioned IM7 coolant and CDA in these manners, the internal chiller subsystem 1500 may support thermal regulation at both the DUT interface and the load-board region, enabling stable operation across cold and hot testing modes and helping maintain desired temperature conditions during parallel DUT testing.

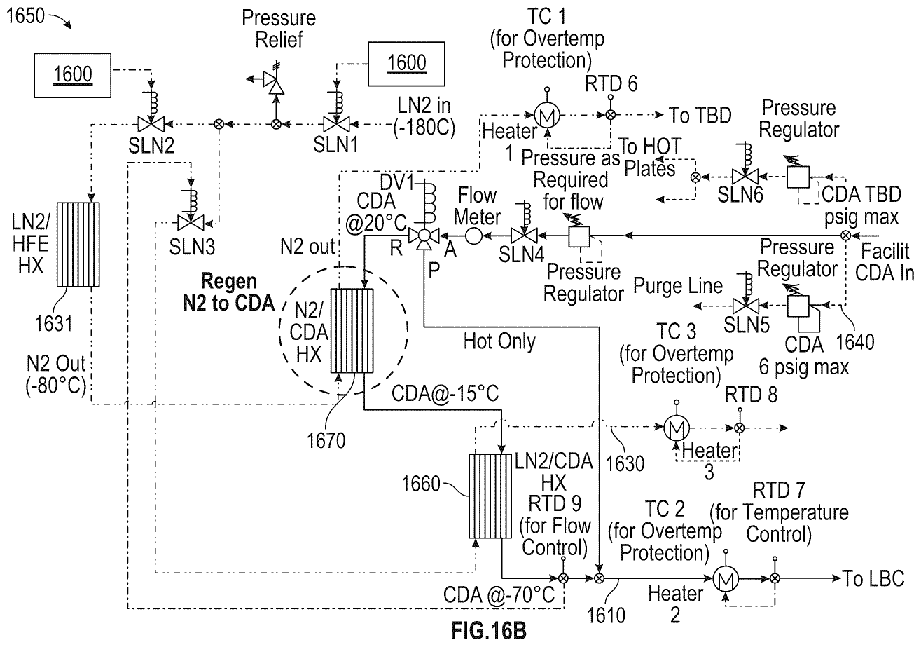

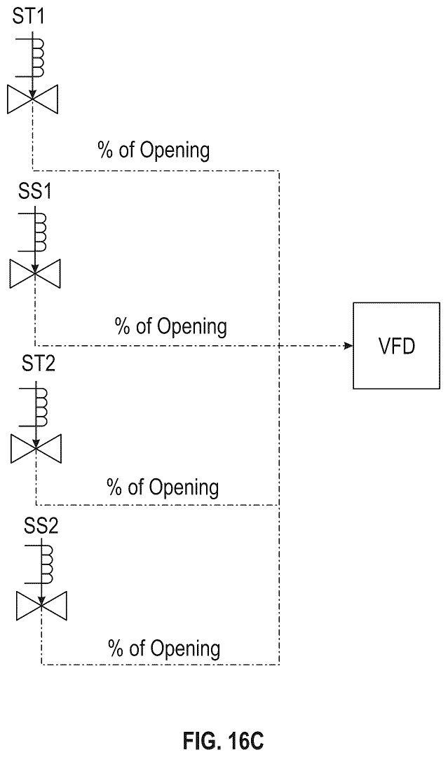

In some embodiments, the internal chiller subsystem 1600 may regulate coolant and refrigerant routing according to the schematic illustrated in FIGS. 16A-16C. In some embodiments, a first portion 1605 of the internal chiller subsystem 1600 may be arranged as shown in FIG. 16A. Portion 1605 may include multiple interacting flow circuits, including a closed-loop coolant circuit 1610 through which a liquid coolant such as IM7 or HFE circulates, an LN₂ refrigerant path 1630, a purge or bypass pathway 1640, and an interconnection pathway 1620 that links to additional chiller components shown in FIG. 16B.

Coolant circuit 1610 may receive coolant from pump 1612, which may circulate coolant through a distribution header supplying proportional valves 1691 (ST1), 1692 (SS1), 1693 (ST2), and 1694 (SS2). Downstream of these valves, coolant may be delivered to Test 1 plate 1616, Soak 1 plate 1615, Test 2 plate 1614, and Soak 2 plate 1613, respectively. After removing heat from these plates, the coolant may return to reservoir 1611. Temperature sensors positioned at or near the plates may provide feedback to regulate coolant flow and the intensity of LN₂-based cooling.

The shared return pathway of circuit 1610 may supply coolant to reservoir 1611, and then back to pump 1612. One or more pressure sensors located near reservoir 1611 may monitor internal pressure levels, and a pressure-relief device may prevent overpressure conditions. A flow meter in the coolant loop may verify that flow satisfies minimum requirements before refrigerant-based cooling is enabled.

Liquid nitrogen may be supplied along LN₂ path 1630. LN₂ path 1630 may include solenoid valves such as SLN1 and SLN3 and a branching segment that directs LN₂ toward heat-exchanger components, including an LN₂ to coolant heat exchange interface 1631 in fluid communication with circuit 1610 (see FIG. 16B). Check valves positioned along LN₂ path 1630 may restrict reverse flow, and a pressure-relief device may limit excessive pressure in the refrigerant circuit. Coolant returning from reservoir 1611 may be routed to an LN₂ to coolant heat-exchange interface 1631, which may be used to extract heat from coolant circuit 1610 using LN₂ delivered along refrigerant path 1630. Path 1630 may include solenoid valves, check valves, and a branch that directs LN₂ toward LN₂ to coolant heat-exchange interface 1631 and toward additional LN₂-based cooling stages shown in portion 1650 of FIG. 16B.

Portion 1605 also includes purge pathway 1640, which may incorporate diverter valve DV2 and may be used to depressurize or purge the system during priming, maintenance, transitions between operating modes, or safety-related events. Interconnection pathway 1620 may link LN₂-based cooling functions of portion 1605 with the CDA conditioning and secondary cooling stages of portion 1650 shown in FIG. 16B.

Together, the components of portion 1605 (e.g., coolant circuit 1610, LN₂ path 1630, purge path 1640, interconnection pathway 1620, pump 1612, reservoir 1611, and LN₂ to coolant heat-exchange interface 1631) represent an upstream portion of the internal chiller architecture, the downstream continuation of which is illustrated in portion 1650 of FIG. 16B.

In some embodiments, a second portion 1650 of the internal chiller subsystem 1600 may be arranged as shown in FIG. 16B. Portion 1650 may operate in conjunction with portion 1605 of FIG. 16A to complete the thermal conditioning functions of the integrated chiller. Whereas portion 1605 may primarily regulate the closed-loop coolant circuit 1610 and LN₂ supply routing, portion 1650 may regulate the conditioning of clean dry air (CDA) used for load-board temperature control and may also include additional LN₂-based evaporator stages that support both the coolant and CDA loops.

As illustrated in FIG. 16B, LN₂ supplied along refrigerant path 1630 may be delivered to multiple heat exchange interfaces. One such interface is the LN₂ to coolant heat-exchange interface 1631 (also shown in FIG. 16A) and may extract heat from coolant circuit 1610. Portion 1650 further includes an LN₂ to CDA heat-exchange interface 1660, which may cool CDA within CDA loop 1680 by direct thermal interaction with liquid nitrogen. In addition, portion 1650 may include an N₂-to-CDA heat-exchange interface 1670, in which cold nitrogen gas generated from upstream LN₂ evaporation may be routed across a secondary CDA cooling stage. These interfaces 1660 and 1670 may operate individually or sequentially to achieve desired CDA outlet temperatures before CDA is delivered to load board conditioning structures such as those described with respect to FIGS. 12A-E.

Portion 1650 may also receive purge or bypass pathway 1640 from portion 1605. That pathway may include diverter valve DV2 and associated check valves and may be used to depressurize lines, isolate sections of the CDA or LN₂ circuits, or redirect flow during priming or safety-response sequences. Interconnection pathway 1620 may similarly allow refrigerant flow paths in portion 1605 to interact with CDA cooling stages in portion 1650, ensuring coordinated operation between coolant-cooling and CDA-cooling functions.

Together, the elements of portion 1650 (e.g., including CDA loop 1680, LN₂ to CDA heat exchange interface 1660, N₂ to CDA heat exchange interface 1670, LN₂ to coolant heat-exchange interface 1631, purge path 1640, and interconnection pathway 1620) can represent the downstream CDA-conditioning and refrigerant-distribution functions of the internal chiller subsystem 1600. When combined with the coolant-handling elements of portion 1605, these components enable the chiller to supply temperature-conditioned coolant to soak plates and test plates, and temperature conditioned CDA to load board conditioning structures, during both cold-mode and hot-mode test operations.

In some embodiments, FIG. 16C illustrates a control portion 1690 of the internal chiller subsystem 1600. As shown, proportional valves 1691 (ST1), 1692 (SS1), 1693 (ST2), and 1694 (SS2) may regulate coolant flow toward Test 1 plate 1616, Soak 1 plate 1615, Test 2 plate 1614, and Soak 2 plate 1613, respectively. These proportional valves may modulate coolant flow based on temperature feedback from corresponding sensors positioned near the soak and test plates. A variable-frequency-drive (VFD) controller 1695 may adjust the rotational speed of pump 1612 based on the operating state of the proportional valves 1691-1694, allowing the system to maintain stable coolant flow under varying thermal loads.

In some embodiments, the internal chiller subsystem may regulate a closed-loop coolant such as HFE or IM7 in accordance with predetermined operating conditions. These conditions may specify recommended ranges or behaviors for coolant flow, valve states, temperature thresholds, and sensor-based control actions under various thermal modes of the system. Table 1 below provides exemplary operating conditions for an HFE coolant loop, including relationships between temperature readings, flow verification requirements, and control responses for system valves and sensors. These conditions are illustrative only and are not intended to be limiting, as different handler configurations or DUT thermal loads may require modified ranges or control parameters.

In some embodiments, temperature sensors positioned at soak plates, test plates, or other coolant-contact regions may provide real-time feedback used to maintain the coolant within a desired temperature range. Flow meter readings and/or or pressure sensor outputs may also be used to ensure that minimum flow and pressure conditions are satisfied before enabling refrigerant-based cooling.

TABLE 1
Exemplary Operating Conditions for HFE Subsystem

| | | | Reference | Desired | Other |
|---|---|---|---|---|---|
| Moniker | Hardware | Purpose | Signal | Operation | Considerations |
| SRV1 | Solenoid | Cold | RTD #1, | If any | For cold start |
| | (NC/24 | Ramping | RTD #2, | RTD > SP + 10 C., | Could be placed on a |
| | DC) | Value, | RTD #3, | Power up | timer |
| | | HFE, | RTD #4, | (valve opens) | |
| | | On/Off | | If any | |
| | | (cold start) | | RTD < SP + 3° C., | |
| | | | | remove power | |
| | | | | (valve closes) | |
| SRV2 | Solenoid | Priming | | For cold start. | |
| | (NC/24 | Value, | | Open for 2 | |
| | DC) | HFE, | | minutes | |
| | | On/Off | | | |
| | | (Cold start) | | | |
| SRV3 | Solenoid | Operating | | Opposite to | |
| | (NC/24 | Value | | SRV2 | |
| | DC) | | | | |
| ST1 | Solenoid | Proportional | RTD #1 | Valve is | |
| | (NC/24 | flow control | | proportionally | |
| | DC) | for Test 1 | | controlled to | |
| | | cold plate | | maintain RTD | |
| | | | | #1 temperature = | |
| | | | | TSP +/− 3° C. | |
| SS1 | Solenoid | Proportional | RTD #2 | Valve is | |
| | (NC/24 | flow control | | proportionally | |
| | DC) | for Soak 1 | | controlled to | |
| | | cold plate | | maintain RTD | |
| | | | | #2 temperature = | |
| | | | | TSP +/− 3° C. | |
| ST2 | Solenoid | Proportional | RTD #3 | Valve is | |
| | (NC/24 | flow control | | proportionally | |
| | DC) | for Test 2 | | controlled to | |
| | | cold plate | | maintain RTD | |
| | | | | #3 temperature = | |
| | | | | TSP +/− 3° C. | |
| SS2 | Solenoid | Proportional | RTD #4 | Valve is | |
| | (NC/24 | flow control | | proportionally | |
| | DC) | for Soak 2 | | controlled to | |
| | | cold plate | | maintain RTD | |
| | | | | #4 temperature = | |
| | | | | TSP +/− 3° C. | |
| VFD | VFD | Pump's | ST #1, | If ALL valves | |
| (cold) | | variable | SS#1, | (ST #1, SS#1, | |
| | | frequency | ST#2, | ST#2, SS#2) | |
| | | drive | SS#2, | are at less than | |
| | | | | 50% then | |
| | | | | decrease pump | |
| | | | | VFD in 5% | |
| | | | | increments as | |
| | | | | needed to | |
| | | | | achieve all | |
| | | | | valves | |
| | | | | percentage > | |
| | | | | 50% up to at | |
| | | | | least one valve | |
| | | | | at 80%. | |
| | | | | If ALL valves | |
| | | | | (ST #1, SS#1, | |
| | | | | ST#2, SS#2) | |
| | | | | are at greater | |
| | | | | than than 80% | |
| | | | | then increase | |
| | | | | pump VFP in | |
| | | | | 5% increments | |
| | | | | as needed to | |
| | | | | achieve all | |
| | | | | valves | |
| | | | | percentage < | |
| | | | | 80%. | |
| Dual | Upper | Trigger for | | When the level | |
| Flow | Level | high fluid | | rises to high- | |
| Switch | Switch | warning in | | level limit, the | |
| | (NC) | reservoir | | switch opens. | |
| | | | | A high-level | |
| | | | | alarm is | |
| | | | | displayed. | |
| | Lower | Trigger for | | When the level | |
| | Level | low fluid | | drops to low- | |
| | Switch | warning in | | level limit, the | |
| | (N0) | reservoir | | switch closes. | |
| | | | | A low-level | |
| | | | | alarm is | |
| | | | | displayed. | |

In some embodiments, the internal chiller subsystem may regulate LN₂ flow and nitrogen-gas discharge conditions in accordance with predetermined operating behaviors. These behaviors may determine how LN₂ control valves open or close based on flow-meter readings, temperature signals, or test setpoint values, and may determine how integrated heaters are operated to prevent condensation at LN₂ exhaust locations. Table 2 below illustrates exemplary operating conditions for LN₂ and nitrogen flow management, including the control logic for solenoid valves, discharge-temperature protection, and heater modulation behavior. These examples are illustrative and are not intended to limit the scope of the system, as variations in DUT power dissipation, ambient conditions, or chiller configuration may require adjustments to the specific thresholds or operating parameters described.

In some embodiments, the controller may disable LN₂ flow when insufficient coolant flow is detected, modulate heaters to maintain nitrogen discharge temperatures within a specified range, or shut off heaters based on specific combinations of valve states and temperature readings. These LN₂/N₂ control conditions may work in concert with the coolant subsystem and CDA subsystem to prevent evaporator freezing, maintain LN₂ vapor above dewpoint temperatures, and ensure stable thermal performance across the range of test operating modes.

TABLE 2
Exemplary Operating Conditions for LN₂/N₂

| | | | Reference | | Other |
|---|---|---|---|---|---|
| Moniker | Hardware | Purpose | Signal | Desired Operation | Considerations |
| SLN1 | Solenoid | Main LN₂ | Flow | Frequency < 19 Hz: | Avoid freezing |
| | (NC/24 | On/Off Valve | meter | Remove power | the evaporator |
| | DC) | | frequency | (valve closes). | when there is |
| | | | | Frequency > 19 Hz: | not sufficient |
| | | | | Power up (valve | flow of HFE on |
| | | | | opens). | the opposite |
| | | | | | side of the |
| | | | | | evaporator. |
| SLN2 | Solenoid | Discrete Flow | RTD#0 | RTD #0 temp > TSP + | |
| | (NC/24 | Control | | 3° C.: Power up | |
| | DC) | | | (valve opens). | |
| | | | | RTD #0 temp < TSP − | |
| | | | | 3° C.: Remove | |
| | | | | power (valve closes). | |
| SLN3 | Solenoid | LBC cold run | RTD#9 | If any TSP < 20° C., | For cold runs |
| | (NC/24 | | | Power up (valve | |
| | DC) | | | opens). | |
| | | | | RTD #9 temp > TSP + | |
| | | | | 3° C.: Power up | |
| | | | | (valve opens). | |
| | | | | RTD #9 temp < TSP − | |
| | | | | 3° C.: Remove | |
| | | | | power (valve closes). | |
| HT1 | Heater | Avoid | RTD #6, | Modulate heater | TC #1 is to be |
| | with | condensation | TC #1 | power accordingly to | used for over |
| | integrated | at the exhaust | | ensure discharge | temperature |
| | TC | of HFE/LN₂ | | temperature is | protection. If |
| | | by heating | | between 15° C. and < | TC #1 > 170° C., |
| | | the N₂ above | | 22° C. | remove power |
| | | the room | | Power OFF heater if | to heater |
| | | dewpoint | | either SLN #1 and/or | (heater OFF). |
| | | temperature | | SLN #2 are closed. | |
| | | | | Power OFF heater if | |
| | | | | discharge | |
| | | | | temperature (RTD | |
| | | | | #6) is > 22° C. | |
| HT3 | Heater | Avoid | RTD #8, | Modulate heater | TC #3 is to be |
| | with | condensation | TC #3 | power accordingly | used for over |
| | integrated | at the exhaust | | such that discharge | temperature |
| | TC | of HFE/LN₂ | | temperature is | protection. If |
| | | by heating | | between 15° C. and < | TC #3 > 170° C., |
| | | the N₂ above | | 22° C. | remove power |
| | | the room | | Power OFF heater if | to heater |
| | | dewpoint | | either SLN #1 and/or | (heater OFF). |
| | | temperature | | SLN #3 are closed. | |
| | | | | Power OFF heater if | |
| | | | | discharge | |
| | | | | temperature (RTD | |
| | | | | #8) is > 22° C. | |

In some embodiments, the internal chiller subsystem may regulate the flow of CDA used for load-board conditioning (LBC). CDA may be directed through one or more LN₂-assisted or bypass flow paths depending on the thermal mode (cold or hot) and the required temperature setpoint for the load board. Control of CDA may be achieved through a combination of solenoid valves, diverting valves, and heaters with integrated temperature control. Table 3 below provides exemplary operating conditions for the CDA/LBC subsystem, including functional behaviors for ON/OFF valves, purge valves, bypass valves, and heater-control logic. These examples are illustrative only and may vary depending on system configuration, DUT requirements, ambient environmental conditions, and the desired load-board temperature profile. In some embodiments, the controller may regulate CDA distribution by enabling or disabling specific valves based on temperature sensors, switching between bypass ports and heat-exchange ports, or modulating heater output to maintain discharge temperature within a defined range. These CDA-control behaviors support load-board temperature uniformity and complement the cooling and heating functions of the coolant and LN₂ subsystems described herein.

TABLE 3
Exemplary Operating Conditions for CDA/LBC

| | | | Reference | Desired | Other |
|---|---|---|---|---|---|
| Moniker | Hardware | Purpose | Signal | Operation | Considerations |
| SLN4 | Solenoid | LBC On/Off | | | |
| | (NC/24 | Valve | | | |
| | DC) | | | | |
| SLN5 | Solenoid | Tank/Purge | | | |
| | (NC/24 | On/Off Valve | | | |
| | DC) | | | | |
| SLN6 | Solenoid | Poppet Pilot | | | |
| | (NC/24 | CDA On/Off | | | |
| | DC) | Valve | | | |
| DV1 | Diverting | LN₂/CDA HX | | Normally open to | |
| (LBC) | valve (24 | bypass | | ports A/R for | |
| | DC) | | | TSP < 20° C. | |
| | | | | When power is | |
| | | | | applied, bypasses | |
| | | | | the heat | |
| | | | | exchanger by | |
| | | | | switching to | |
| | | | | ports A/P. | |
| DV2 | Diverting | HFE | | Normally open to | |
| | valve (24 | tank/system | | ports 2/3 to | |
| | DC) | purge bypass | | pressurize the | |
| | | | | HFE reservoir. | |
| | | | | When power is | |
| | | | | applied, diverts | |
| | | | | the flow to the | |
| | | | | cold plates for | |
| | | | | purging HFE | |
| | | | | back to the tank. | |
| HT2 | Heater | Provide | RTD #7, | Modulate heater | TC #1 is to be |
| (LBC, | with | desired | TC #2 | power | used for |
| Hot | integrated | temperature | | accordingly to | overtemperature |
| only) | TC | for Hot | | ensure discharge | protection. |
| | | temperature | | temperature is | If TC #1 > |
| | | runs | | between TSP ± | 170° C., remove |
| | | | | 3° C. | power to heater |
| | | | | Power OFF | (heater OFF). |
| | | | | heater if SLN #4 | |
| | | | | is closed. | |
| | | | | Power OFF | |
| | | | | heater if | |
| | | | | discharge | |
| | | | | temperature | |
| | | | | (RTD #7) is > | |
| | | | | 22° C. | |

In some embodiments, the internal chiller subsystem may incorporate one or more safety mechanisms configured to detect fault conditions and place the system into a controlled shutdown state. An emergency shutdown may be triggered when the subsystem determines that the coolant circuit, refrigerant circuit, or reservoir conditions indicate the potential for unsafe operation. In some examples, the chiller controller may be configured to initiate an emergency shutdown when any two of the following conditions are present: (i) pressure transducer 1 (PT #1) indicates zero pressure, (ii) pressure transducer 2 (PT #2) indicates zero pressure, (iii) the coolant-flow meter indicates zero flow, and/or (iv) a low-level warning is detected in the coolant reservoir. These indicators may correspond to insufficient coolant circulation, refrigerant starvation, or loss of system pressure, any of which may pose a risk of evaporator freeze, pump cavitation, or inadequate heat removal.

Upon detecting any such combination of conditions, the controller may execute an emergency shutdown procedure. In some embodiments, this procedure may comprise disabling refrigerant flow by closing solenoid valves SLN1, SLN2, and/or SLN3; shutting off the coolant pump; actuating diverter valve DV2 to place the chiller into a purge or pressure-relief configuration; and fully opening proportional valves 1691 (ST1), 1692 (SS1), 1693 (ST2), and/or 1694 (SS2). Opening these proportional valves may relieve residual hydraulic pressure within coolant circuit 1610 and facilitate safe depressurization. This coordinated shutdown sequence may prevent component damage, inhibit the formation of frozen LN₂ at the evaporator, and ensure the subsystem enters a stable and diagnosable state.

In some embodiments, the internal chiller subsystem may utilize multiple temperature sensors, pressure sensors, and flow-monitoring devices to generate control signals for solenoid valves, proportional valves, heaters, and pump-speed regulation. Table 4 below lists exemplary signal sources and their associated control functions within the chiller system. These examples are not limiting, and alternative sensor assignments or sensing technologies may be used depending on system requirements, hardware configuration, or controller design. Such signals may allow the controller to regulate LN₂ flow, coolant flow, CDA conditioning, heater activation, or pump speed based on measured conditions at thermal plates, heat-exchange interfaces, or refrigerant discharge points.

TABLE 4
Control Signals and Sensor Associations

| Hardware | Purpose |
|---|---|
| RTD #0 | Provides control signal for Solenoid |
| | SLN2 |
| RTD #1 | Provides control signal for Solenoid ST1 |
| RTD #2 | Provides control signal for Solenoid SS1 |
| RTD #3 | Provides control signal for Solenoid ST2 |
| RTD #4 | Provides control signal for Solenoid SS2 |
| RTD #5 (HOT RUNS) | Provides control signal for VFD |
| RTD #6 | Provides control signal for Heater HT1 |
| RTD #7 | Provides control signal for Heater HT2 |
| RTD #8 | Provides control signal for Heater HT3 |
| RTD #9 | Provides control signal for Solenoid |
| | SLN3 |
| Flow meter | Provides signal for SLN1 |

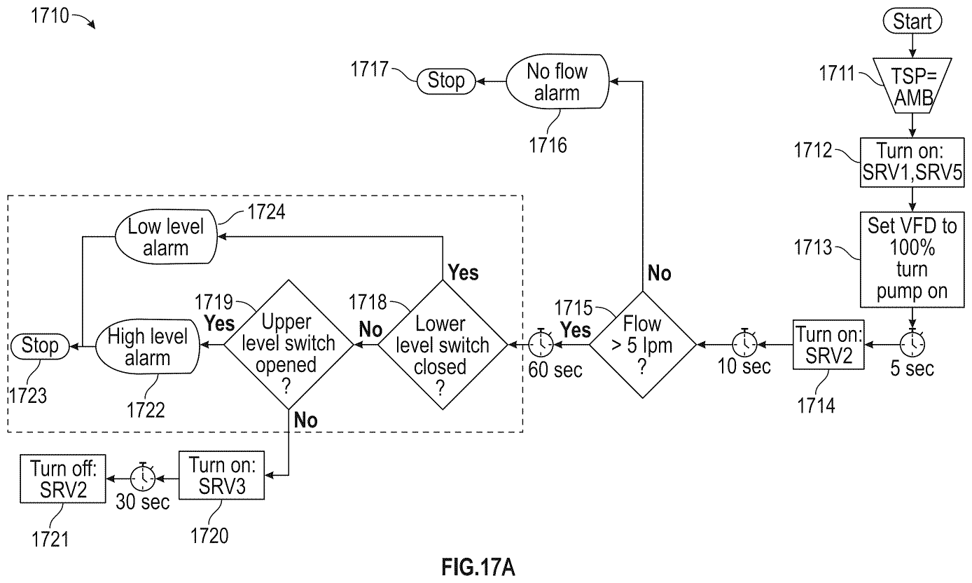

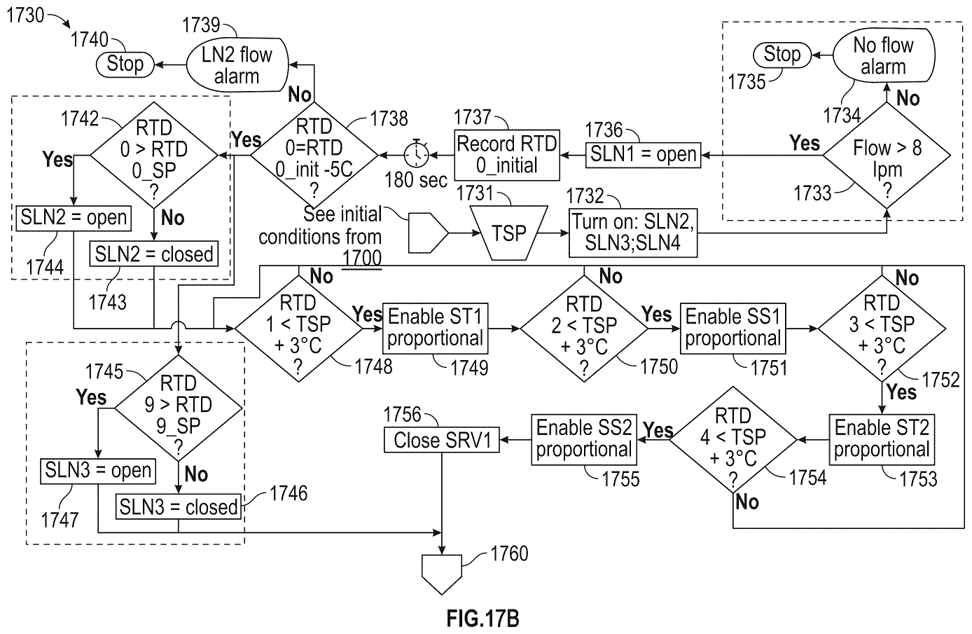

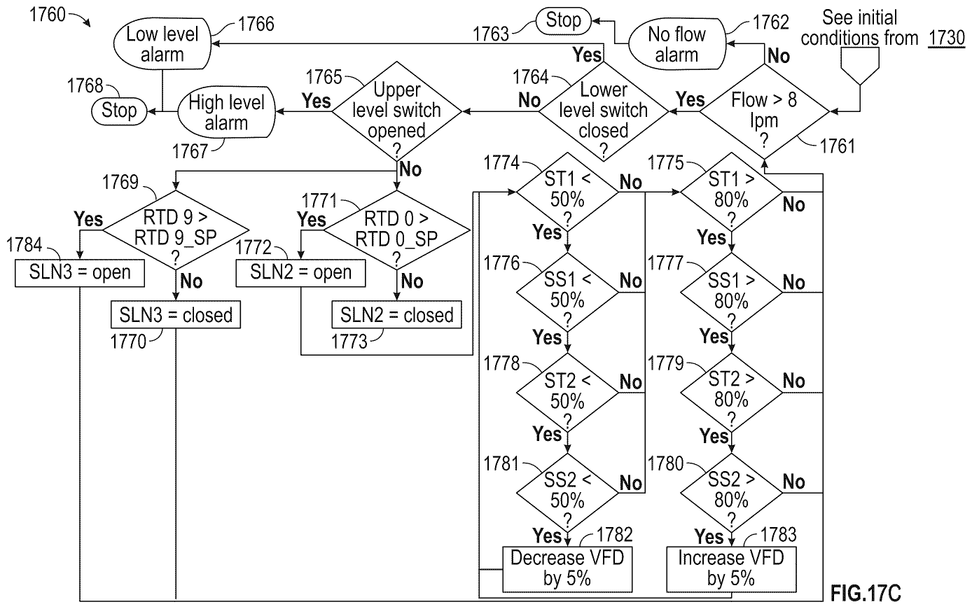

In some embodiments, FIG. 17A illustrates a priming sequence 1710 that may be executed when the internal chiller subsystem 1600 is first filled with coolant or after the system has been drained prior to restart. The sequence may begin by setting the test setpoint temperature (TSP) to ambient as shown in step 1711. The controller may then turn ON SRV1 in step 1712 to place the system into a priming mode, with other valves such as SRV2 and SRV3 initially held closed.

Before initiating coolant flow, the controller may ensure that SRV2 and SRV3 are de-energized (e.g., closed), and may turn ON SRV1 in step 1712, placing the subsystem into a priming-enabled configuration. In some embodiments, the controller may also energize SLN5 to apply a small pressurization (e.g., approximately 6 psi) to the reservoir to assist with priming.

The controller may then set the pump's VFD to its initial priming value and turn the pump ON in step 1713. After allowing the pump to run briefly (e.g., for 10 seconds), the system may open SRV2 to begin drawing coolant into circulation. The controller may then evaluate whether coolant flow has been established; if flow is not detected, the logic may route to the “no flow” alarm condition shown in step 1716 and then proceed to a stop condition at step 1717, thereby terminating the priming attempt.

If flow is detected after SRV2 is opened, the controller may allow the system to continue circulating coolant for approximately one minute. The system may then evaluate reservoir level-switch states. Step 1718 represents evaluation of the lower-level switch; if the lower-level switch is closed (YES), indicating insufficient coolant volume, the sequence may proceed directly to the low-level alarm at step 1724. In this case, the operator may be prompted to stop the sequence, add coolant to the reservoir, and restart priming from step 1711.

If the lower-level switch is not closed (NO at step 1718), the controller may next evaluate the upper-level switch in step 1719. If the upper-level switch is opened (YES), indicating an overfill or high-level condition, the sequence may transition to the high-level alarm at step 1722 and terminate the priming process. If neither level alarm is present (NO at step 1719), the system may proceed with the remainder of the priming routine.

Once flow and level conditions are confirmed acceptable, the controller may turn ON SRV3 in step 1720 to complete establishment of the desired recirculation path. After an additional stabilization period (e.g., about 30 seconds) the controller may turn OFF SRV2 in step 1721. The system may then proceed to a normal stop condition at step 1723, indicating that the priming sequence has completed successfully. Step 1722 and step 1724 illustrate stop conditions associated with high-level and low-level alarms, respectively.

Through these operations, the priming sequence ensures that coolant circuit 1610 is fully purged of trapped air, reservoir 1611 is at an acceptable level, and pump 1612 is delivering adequate flow prior to initiating cold-ramping or steady-state cooling modes.

In some embodiments, FIG. 17B illustrates a cold-ramping sequence 1730 that may be executed after the priming sequence 1710 has been successfully completed. The starting conditions for sequence 1730 may include pump ON with the VFD operating at approximately 60 Hz, valves SRV1, SRV3, and SLN5 energized (open), and substantially all other valves in their de-energized state (e.g., closed or in a normal diverting mode, depending on valve type).

As shown in FIG. 17B, the controller may begin the cold-ramping sequence by establishing a test setpoint temperature (TSP) in step 1731. Based on the selected TSP, the controller may compute a corresponding desired set value for RTD0 (RTD0_SP), for example by applying a fixed offset from TSP. In step 1732, the controller may energize LN₂ control valves SLN2, SLN3, and SLN4 to admit LN₂ into the cooling circuitry. The controller may then verify that coolant flow is adequate; in decision step 1733 it may determine whether the flow meter indicates a flow greater than a predefined threshold (e.g., about 8 lpm at 60 Hz). If the measured flow does not exceed this threshold, the sequence may branch to a “NO FLOW ALARM” condition 1734 and then proceed to STOP 1735, terminating the cold-ramping attempt.

If flow is adequate, the controller may open SLN1 in step 1736 to route LN₂ through the corresponding heat-exchange path. The controller may then record an initial value of RTD0 (RTD0_initial) in step 1737 and allow the system to run for a ramp interval (for example, approximately 180 seconds). After this interval, decision step 1738 may evaluate whether RTD0 has decreased by at least a threshold amount relative to the initial value (e.g., RTD0<RTD0_initial−5° C.). If the required temperature drop is not achieved, the logic may branch to an LN₂ flow alarm 1739 and then to STOP 1740, indicating that adequate cooling has not been established. If the required drop is achieved, the sequence may proceed to more finely controlled LN₂ regulation.

In some embodiments, SLN2 may be modulated to control the temperature sensed by RTD0. Decision step 1742 may determine whether RTD0 exceeds its setpoint (e.g., RTD0>RTD0_SP). If RTD0 is above the setpoint, the controller may open SLN2 (step 1744) to increase LN₂ flow and further reduce temperature. If RTD0 is at or below the setpoint, the controller may close SLN2 (step 1743) to reduce or stop LN₂ flow along that path. This loop may repeat as needed to maintain RTD0 near the desired value.

Similarly, SLN3 may be used to regulate a temperature monitored by RTD9. Decision step 1745 may determine whether RTD9 exceeds its corresponding setpoint (e.g., RTD9>RTD9_SP). If so, the controller may open SLN3 (step 1747) to increase LN₂ flow, whereas if RTD9 is at or below the setpoint the controller may close SLN3 (step 1746). This provides independent LN₂-based control of RTD9 while RTD0 is regulated via SLN2.

As the system ramps toward the desired cold condition, additional checks may be performed to enable proportional control of the thermal plates. Decision step 1748 may determine whether RTD1 has dropped below TSP+3° C.; if so, step 1749 may enable proportional control of ST1. Decision step 1750 may similarly determine whether RTD2 is below TSP+3° C.; if so, proportional control of SS1 may be enabled in step 1751. Decision step 1752 may evaluate whether RTD3 is below TSP+3° C., and if so, step 1753 may enable proportional control of ST2. Decision step 1754 may evaluate whether RTD4 is below TSP+3° C., and if so, step 1755 may enable proportional control of SS2. In this manner, each plate may be brought into proportional control only after its corresponding temperature has approached the desired cold operating band, thereby avoiding overshoot or unstable behavior.

Once flow is adequate, LN₂ cooling has been verified, and the relevant plates are under proportional control, the controller may close SRV1 in step 1756 to end the cold-ramping sequence and transition to a subsequent cold-control sequence represented by 1760 (e.g., the controlling-cold sequence of FIG. 17C). This coordinated procedure may ensure that coolant flow, LN₂ flow, and plate temperatures are all within acceptable ranges before steady-state cold operation begins, while providing flow and temperature and clearly defined alarm paths for handling abnormal conditions.

In some embodiments, FIG. 17C illustrates a controlling cold sequence 1760 that may be executed after both the pump-priming sequence 1710 and the cold-ramping sequence 1730 have completed. At the beginning of this sequence, the starting conditions may include pump 1612 ON with the VFD operating at approximately 60 Hz, valves SLN1, SLN2 (controlling), SLN3 (controlling), SLN4, SLN5, and SRV3 energized, and proportional coolant valves ST1, SS1, ST2, and SS2 operating in proportional control mode. All other valves may be de-energized (e.g., closed or in a normal diverting mode, depending on valve type).

Upon entering the controlling-cold mode sequency 1760, the controller may first confirm that coolant flow remains adequate. In step 1761, the controller may determine whether the flow meter indicates a flow greater than a threshold, such as about 8 lpm at 60 Hz. If the flow condition is not met, the logic may transition to a no flow alarm state in step 1762 and then to a stop state in step 1763, thereby terminating cold control until the flow condition is corrected. If the flow condition is satisfied, the controller may next evaluate reservoir level conditions. Decision step 1764 may determine whether a lower level switch is closed, indicating a low level condition in the reservoir; if so, the controller may assert a low level alarm in step 1766, which may lead to stop state 1768. If the lower level switch is not closed, the controller may evaluate the upper level switch in step 1765; if the upper level switch is opened, indicating a high level or overfill condition, the controller may assert a high level alarm in step 1767 and again stop at 1768. If neither level alarm is present, the sequence proceeds to steady-state cooling control.

To maintain a desired CDA or LBC temperature associated with RTD9, the controller may modulate valve SLN3 based on the temperature difference between RTD9 and its setpoint. In decision step 1769, the controller may determine whether RTD9 is greater than a corresponding setpoint (RTD9_ST). If RTD9 exceeds its setpoint, the controller may open SLN3 in step 1784 to increase LN₂ flow and provide additional cooling. If RTD9 is at or below the setpoint, the controller may close SLN3 in step 1770 to reduce LN₂ flow. This loop may repeat continuously, thereby regulating the RTD9 temperature during steady-state cold operation.

Similarly, valve SLN2 may be modulated to control the temperature sensed by RTD0. In decision step 1771, the controller may determine whether RTD0 exceeds its associated setpoint (RTD0_ST). If RTD0 is greater than the setpoint, SLN2 may be opened in step 1773 to increase LN₂ flow to the corresponding heat exchanger. If RTD0 is at or below the setpoint, SLN2 may be closed in step 1772 to decrease LN₂ flow.

In addition to LN₂ valve modulation, the controlling-cold sequence may adjust pump speed based on the utilization of the proportional coolant valves ST1, SS1, ST2, and SS2. A first chain of decision steps may determine whether each of these valves is operating below a lower utilization threshold, such as 50% open. Specifically, step 1774 may check whether ST1 is less than 50% open; step 1776 may check whether SS1 is less than 50% open; step 1778 may check whether ST2 is less than 50% open; and step 1781 may check whether SS2 is less than 50% open. If any of these conditions is not satisfied (e.g., any valve is at or above 50%), the sequence may branch to the high-utilization chain beginning at step 1775. If all four valves are determined to be less than 50% open, the controller may conclude that overall flow is higher than needed and may decrease pump speed by a small increment, for example by decreasing the VFD output by about 5%, as indicated by step 1782. After adjusting the VFD, the logic may loop back to step 1774 and re-evaluate valve utilizations.

If the low-utilization chain does not indicate that all four valves are below 50% open, the sequence may enter a second chain of decisions that check for high utilization. In steps 1775, 1777, 1779, and 1780, the controller may determine whether each of ST1, SS1, ST2, and SS2, respectively, is greater than a higher threshold, such as 80% open. If any of these conditions is not met, the system may loop back to step 1761 to continue monitoring without changing pump speed. If all four valves are operating above the high threshold, the controller may conclude that additional flow is required and may increase the pump VFD by a small increment (e.g., 5%) as indicated by step 1783. After increasing the VFD, the logic may again return to step 1774 to continue evaluating valve utilizations.

The controlling-cold sequence 1760 may maintain the desired temperatures at RTD0 and RTD9 while adaptively adjusting pump speed so that the proportional valves operate within an efficient range between about 50% and 80% open. This can provide stable, efficient steady-state cold operation following the priming and cold-ramping sequences.

In some embodiments, a hot-ramping sequence may be executed after the pump-priming sequence 1710 has been completed and the system is prepared to transition from a non-heated state to a temperature elevation mode. The hot-ramping procedure may begin with pump 1612 operating at a nominal speed (e.g., VFD at approximately 60 Hz) and valves such as SRV1, SRV3, and SLN5 in an energized state, while substantially all other valves remain de-energized. The subsystem may sequentially depressurize coolant lines, isolate cold-plate flows, and enable proportional control valves in a controlled fashion to prevent thermal shock or pressure-related disturbances.

In some embodiments, the controller may initiate hot ramping by energizing SLN6 and maintaining that state for a short interval (e.g., approximately one minute) to prepare associated lines for the transition. The pump may then be turned OFF, after which SRV1 and SRV3 may be de-energized to isolate the coolant distribution paths. The controller may subsequently actuate diverting valve DV2 to depressurize the reservoir and flush coolant from the cold-plate branch associated with ST1.

Following depressurization, the controller may fully open proportional valve ST1 to 100% to ensure that coolant previously present in the corresponding cold plate is effectively displaced. The system may then maintain this condition for a selected period (e.g., an initial estimate of approximately 120 seconds or another duration determined empirically). If, after this period, the RTD0 temperature has not increased by more than approximately 5° C. from its initial value, the system may de-energize SLN1 and SLN2 and declare an LN₂ flow alarm, indicating that required heating conditions have not been met.

If the temperature conditions are satisfied, the controller may then close proportional valve SS1 and reopen SS1 to 100%, repeating the same timed-evaluation procedure described above for ST1. Similar sequences may be performed for ST2 and SS2: valve ST2 may be closed and reopened to 100% to flush the second test plate branch, followed by closing and reopening of SS2 to 100% to flush the second soak-plate branch, with each iteration repeating a waiting interval and temperature-rise verification.

Once flushing and warmup verification have been completed for all plates, the controller may turn OFF DV2 and energize SRV2 and SLN4 to reestablish coolant routing through the desired paths. Proportional valves ST1 and ST2 may then be enabled to regulate flow toward each cold plate in accordance with their respective temperature targets. In some embodiments, DV1 may additionally be actuated to bypass cold-air delivery structures used during LBC operation so that the load board is not actively cooled during hot ramping.

The controller may subsequently restart the pump and read initial values for RTD0 and RTD5. As a safety measure, the controller may again verify that coolant flow exceeds a predetermined threshold (e.g., approximately 8 lpm at 60 Hz). The desired piston-block test setpoint temperature may then be established. Because the heat source during hot-mode operation is derived from the piston block rather than the chiller subsystem, software may set the temperature setpoint directly at the piston block rather than through the internal chiller.

Following setpoint establishment, SLN2 may be energized to regulate the coolant loop. In some embodiments, the controller may close SLN2 if RTD0 falls below approximately 22° C. SLN1 may then be energized, and SLN2 may be modulated as needed to achieve a target value at RTD5 corresponding to a desired thermal condition (e.g., approximately 60° C.). After an additional warm-up period (e.g., approximately 10 minutes, or another duration determined empirically), the controller may evaluate whether RTD5 has risen by more than approximately 5° C. relative to its initial value; if not, SLN1 and SLN2 may be de-energized and the system may raise a temperature timeout alarm. Once satisfactory heating has been confirmed, the controller may modulate the heater associated with RTD7 (e.g., HEATER 3) to maintain the desired RTD7 temperature.

Through these operations, the hot ramping sequence may safely transition the coolant and load-board-conditioning circuits from cold or ambient conditions into elevated-temperature operation while enabling multiple proportional control stages, verifying temperature response at nodes RTD0, RTD5, and RTD7, and ensuring that coolant distribution and refrigerant-valve states are appropriately configured for subsequent hot steady-state testing.

In some embodiments, a running hot mode may be executed after completion of the pump-priming and hot-ramping sequences. At the beginning of this mode, the pump may be ON with the VFD operating at approximately 60 Hz, and valves SRV2, ST1, ST2, SLN1, SLN2, SLN4, SLN5, SLN6, and DV1 may be energized, while all other valves remain de-energized or in their normal diverting configuration.

Running hot operation may begin by verifying that coolant flow remains above a desired threshold, such as greater than approximately 8 lpm at 60 Hz. The system may also confirm that the reservoir's low level sensor is not triggered, ensuring adequate coolant volume in reservoir 1611. Once these preliminary conditions are satisfied, the controller may regulate the temperature at RTD5 by modulating SLN2 to adjust the amount of LN₂-based cooling applied to the coolant loop. Additional heating may be performed by controlling HEATER 3 to achieve a desired value at RTD7, allowing the system to maintain a stable hot operating condition suitable for elevated-temperature test modes.

During the hot running state, the system may continually evaluate the opening percentages of proportional valves ST1, SS1, ST2, and SS2. If all four proportional valves are operating below a lower utilization threshold, such as less than approximately 50% open, the controller may reduce pump speed by decreasing the VFD output in small increments, for example by 5%, until at least one valve returns to a more moderate opening percentage (e.g., at least one valve approaching approximately 80% open). Conversely, if all four proportional valves are operating above an upper utilization threshold, such as greater than approximately 80% open, the controller may increase pump speed by raising the VFD output in similar increments to ensure adequate coolant delivery and maintain proportional valve operation within an efficient range. These adjustments may repeat continuously, allowing the controller to maintain stable flow conditions and temperature regulation throughout extended hot-mode operation.

Through coordinated modulation of SLN2, HEATER 3, and pump-VFD output, the running-hot sequence may provide stable heating performance while ensuring that proportional coolant-control valves operate within a desired range, thereby supporting reliable temperature control during hot-test cycles.

In some embodiments, the internal chiller subsystem may include procedures for establishing a desired CDA hot-valve pressure used during hot-mode load-board conditioning. To determine the appropriate pressure, the system may be operated in a stable circulating state in which pump 1612 is ON and driven at a nominal speed, such as approximately 60 Hz, and valves such as SRV2, ST1, ST2, and SLN5 are energized, while all other valves remain de-energized or in their normal diverting modes. Under these conditions, the system may record the value indicated by pressure transducer 2 to establish a reference pressure associated with CDA supply routing.

A pressure regulator located upstream of valve SLN6 may then be adjusted to a pressure approximately 5 psi greater than the value reported by pressure transducer 2, but no less than about 50 psi. This adjustment may ensure that CDA routed through SLN6 reaches the desired hot-valve pressure for subsequent conditioning operations and that adequate upstream pressure is available for stable CDA flow during hot-mode operation.

In some embodiments, the internal chiller subsystem may also provide a controlled procedure for setting CDA tank pressure and purge pressure used during priming, venting, or reservoir maintenance operations. With pump 1612 off, the system may energize SLN5 while maintaining all other valves in their de-energized states. A pressure regulator located upstream of SLN5 may then be adjusted to establish a reference pressure level, such as approximately 7 psi, corresponding to the desired tank or purge pressure.

A pressure relief valve connected to the associated CDA manifold or reservoir may then be adjusted to open at the reference pressure setting. The upstream pressure regulator associated with SLN5 may subsequently be adjusted to a slightly lower value, such as approximately 6 psi, to verify that no CDA flow is present at the relief valve outlet. If flow is detected, the relief valve setting may be incrementally increased until the condition is resolved. Once the desired relationship between the regulator and the relief valve has been established, the regulator setting may be rechecked by briefly returning it to the higher reference pressure and confirming that the relief valve opens at the expected threshold. This coordinated regulator and relief-valve adjustment process may ensure proper CDA pressurization of the tank and stable purge behavior during system startup and maintenance procedures.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A thermal control system comprising:
one or more thermal heads configured to simultaneously control a temperature of a plurality of devices under test (DUTs), at least one of the thermal heads comprising:
one or more heat exchanger assemblies (HEAs) configured to heat or cool one or more piston block assemblies (PBAs);
wherein the one or more PBAs are configured to apply force to one or more plate assemblies and transfer heat or cooling to the one or more plate assemblies; and
wherein the one or more plate assemblies are configured to heat or cool the plurality of DUTs.

2. The thermal control system of claim 1, wherein the plurality of DUTs comprises more than 32 DUTs.

3. The thermal control system of claim 1, wherein at least one of the one or more HEAs comprise one or more of: a liquid-cooled cold plate, a cooling medium, a Peltier device, or a heat exchanger configured to adjust one or more temperatures of the one or more HEAs.

4. The thermal control system of claim 1, wherein at least one of the PBAs comprises one or more piston blocks, at least one of the one or more piston blocks comprising one or more pistons.

5. The thermal control system of claim 4, wherein at least one of the PBAs comprises one or more seal rings.

6. The thermal control system of claim 4, wherein at least one of the one or more piston blocks further comprises one or more pivots comprising a curved surface configured to fit against a curved surface of the one or more pistons, wherein the one or more pivots are configured to rotate to apply constant force to a receiving surface of at least one of the one or more plate assemblies.

7. The thermal control system of claim 6, wherein the one or more piston blocks further comprise one or more thermal interfaces configured to transfer heat between the one or more pistons and the one or more pivots.

8. The thermal control system of claim 1, wherein at least one of the one of more plate assemblies comprises:
one or more pusher blocks, at least one of the one or more pusher blocks comprises one or more mandrels;
one or more pedestals attached to the one or more pusher blocks; and
one or more flex film heaters, wherein the one or more flex film heaters are flexible and configured to transfer heat to at least one of the one or more pusher blocks.

9. The thermal control system of claim 8, wherein at least one of the one or more plate assemblies comprises the one or more flex film heaters coupled to at least one of the one or more pusher blocks, wherein the one or more flex film heaters are configured to individually adjust a temperature of at least one of the pedestals.

10. The thermal control system of claim 8, wherein a portion of at least one of the one or more flex film heaters is wrapped around at least one of the one or more mandrels, and the at least one mandrel is configured to push the portion of the at least one flex film heater into contact with the at least one pusher block.

11. The thermal control system of claim 8, wherein at least one of the one or more flex film heaters comprises traces configured to provide heat, sense temperature, or both.

12. The thermal control system of claim 8, wherein at least one of the one or more flex film heaters comprises a connector at a distal tip configured to connect to power delivery circuitry configured to deliver power to the one or more flex film heaters.

13. The thermal control system of claim 1, further comprising a demultiplexer configured to control a temperature of a plurality of zones of the one or more thermal heads.

14. The thermal control system of claim 1, wherein at least one of the one or more plate assemblies comprises:
one or more pusher blocks;
one or more pedestals attached to the one or more pusher blocks;
one or more rigid heaters positioned between the one or more pusher blocks and the one or more pedestals, wherein the one or more rigid heaters are configured to heat the one or more pedestals; and
one or more flex cables or wires electrically coupled to the one or more rigid heaters, wherein the one or more flex cables or wires are configured to supply voltages or currents to the one or more rigid heaters.

15. The thermal control system of claim 14, wherein the at least one plate assembly comprises the one or more rigid heaters coupled to each of the one or more pusher blocks, wherein the one or more rigid heaters are configured to individually adjust a temperature of the one or more pedestals.

16. The thermal control system of claim 1, further comprising one or more convective flow channels configured to carry temperature conditioned air.

17. The thermal control system of claim 1, further comprising one or more conductive temperature conditioning structures including one or more internal fluid channels configured to transfer heat to or from one or more structures configured to support or electrically couple the DUTs.

18. The thermal control system of claim 1, further comprising one or more internal fluid-delivery pathways configured to route temperature conditioned fluid to one or more temperature-conditioning structures.

19. The thermal control system of claim 1, further comprising one or more thermal controllers configured to control a temperature of the one or more thermal heads.

20. The thermal control system of claim 19, wherein the one or more thermal controllers comprise one or more FPGAs and a plurality of demultiplexed channels configured to control the temperature of the plurality of DUTs.

21. The thermal control system of claim 1, further comprising a thermal conditioning subsystem configured to supply temperature conditioned fluid to the one or more HEAs.

22. A method for temperature-controlled device testing, comprising:
inserting a plurality of devices under test (DUTs) into a plurality of sockets of a testing tray;
positioning one or more pedestals of one or more thermal heads against the plurality of DUTs;
changing a temperature of the plurality of DUTs to a first temperature by changing a temperature of the one or more pedestals to the first temperature;
testing the DUTs at the first temperature;
changing the temperature of the plurality of DUTs to a second temperature by changing a temperature of the one or more pedestals to the second temperature, wherein the second temperature is different than the first temperature; and
testing the DUTs at the second temperature.

23. The method of claim 22, further comprising controlling a force with which the plurality of DUTs are inserted into the plurality of sockets.

24. A test handler system comprising:
a pick and place head comprising a plurality of pick tips configured to pick up a plurality of devices under test (DUTs),
wherein at least one of the pick tips comprises a plurality of positioning mechanisms, the plurality of positioning mechanisms comprising:
a first positioning mechanism for adjusting a position of the pick tip in a first direction; and
a second positioning mechanism for adjusting a position of the pick tip in a second direction, wherein a configuration of the plurality of DUTs is adjusted while holding the plurality of DUTs from the plurality of pick tips.

25. The test handler system of claim 24, wherein the pick and place head is configured to regulate a force applied by the pick tips to the plurality of DUTs based on a user-selected force setpoint.

26. A thermal conditioning subsystem comprising:
a primary refrigerant circuit configured to receive a primary refrigerant;
a first fluid circuit configured to circulate a first fluid;
a second fluid circuit configured to circulate a second fluid;
a first heat exchange interface configured to transfer heat between the primary refrigerant and the first fluid; and
a second heat exchange interface configured to transfer heat between the primary refrigerant and the second fluid,
wherein the subsystem is configured to supply the first fluid and the second fluid to one or more temperature controlled elements of a test system.
